(19) United States
(12) Patent Application Publication
(10) Pub. No.: US 2023/0197532 A1
(43) Pub. Date: Jun. 22, 2023

(54) PREDICTION OF WAFER FLATNESS

(71) Applicant: Yangtze Memory Technologies Co., Ltd., Wuhan (CN)

(72) Inventors: Xin LEI, Wuhan (CN); Ying CHOU, Wuhan (CN); HaoJie SONG, Wuhan (CN); Kun BAO, Wuhan (CN); Fan WANG, Wuhan (CN); Guoxiu JIN, Wuhan (CN)

(73) Assignee: Yangtze Memory Technologies Co., Ltd., Wuhan (CN)

(21) Appl. No.: 17/875,860

(22) Filed: Jul. 28, 2022

Related U.S. Application Data
(63) Continuation of application No. PCT/CN2021/138711, filed on Dec. 16, 2021.

(51) Int. Cl. H01L 21/66; H01L 25/065; H01L 25/18; H01L 23/00; H01L 25/00; G06N 5/04

(52) U.S. Cl. CPC H01L 22/12; H01L 25/0657; H01L 25/18; H01L 24/08; H01L 24/80; H01L 25/50; G06N 5/04; H01L 2224/08145; H01L 2224/80895; H01L 2224/80896; H01L 2924/1431; H01L 2924/14511

(57) ABSTRACT

Aspects of the disclosure provide methods for determining wafer flatness and for fabricating a semiconductor device. The method includes storing a first wafer expansion of a first wafer that is collected along a first direction parallel to a working surface of the first wafer during a lithography process. The lithography process is for patterning structures on the working surface of the first wafer. Before a fabrication step with a wafer flatness requirement, a wafer flatness of the first wafer is determined based on the first wafer expansion collected during the lithography process using a flatness prediction model that is configured to predict the wafer flatness. In an example, a layer is deposited on a back side of the first wafer with a thickness that is based on the determined wafer flatness of the first wafer.

### TECHNICAL FIELD

The present application describes embodiments generally related to semiconductor memory devices and fabrication of semiconductor memory devices.

### BACKGROUND

A semiconductor device can be formed by various fabrication steps performed on a wafer. The fabrication steps can affect flatness (e.g., a bow) of the wafer. Certain fabrication step, such as a wafer level bonding of a first wafer and a second wafer, can have a flatness requirement of the flatness of the wafer. However, the first wafer and/or the second wafer can have a relatively large bow, making it challenging for the wafer level bonding. It is desirable to measure the bow of the wafer, and subsequently reduce the bow to satisfy the flatness requirement.

### SUMMARY

Aspects of the disclosure provide a method for determining wafer flatness. The method can include storing a first wafer expansion of a first wafer that is collected along a first direction parallel to a working surface of the first wafer during a lithography process for patterning structures on the working surface of the first wafer. Before a fabrication step with a wafer flatness requirement, a wafer flatness of the first wafer can be determined based on the first wafer expansion collected during the lithography process using a flatness prediction model that is configured to predict the wafer flatness.

In an embodiment, the method includes depositing a layer on a back side of the first wafer with a thickness that is based on the determined wafer flatness of the first wafer.

In an embodiment, the method further includes measuring a second wafer expansion along a second direction parallel to the working surface of the first wafer where the first direction can be perpendicular to the second direction. The method further includes determining the wafer flatness of the first wafer based on the first wafer expansion and the second wafer expansion using the flatness prediction model.

In an embodiment, the method further includes, after the lithography process and prior to the determining step, modifying the first wafer by forming the structures on the working surface of the first wafer using a plurality of fabrication steps. The wafer flatness of the first wafer can be determined based on the first wafer expansion and a wait time between two of the plurality of fabrication steps using the flatness prediction model.

In an embodiment, the wafer flatness is indicated by a bow of the first wafer, the flatness prediction model is a bow prediction model that predicts the bow of the first wafer, and the method includes determining the bow of the first wafer based on the first wafer expansion using the bow prediction model.

In an embodiment, the flatness prediction model is based on a machine learning algorithm, and the method further includes measuring a wafer expansion of a second wafer along a direction that is parallel to the working surface of the second wafer during a lithography process for patterning structures on the working surface of the second wafer. Before the fabrication step with the wafer flatness requirement is performed on the second wafer, a wafer flatness of the second wafer can be determined based on the wafer expansion of the second wafer using the flatness prediction model. The method includes measuring an actual wafer flatness of the second wafer and updating the flatness prediction model based on the measured wafer flatness of the second wafer and the determined wafer flatness of the second wafer.

In an embodiment, the lithography process is a lithography process that is performed closest in time to the fabrication step with the wafer flatness requirement.

In an embodiment, the wafer flatness of the first wafer is determined based on a processing temperature or a processing time of one of the plurality of fabrication steps using the flatness prediction model. The flatness prediction model can be dependent on the first wafer expansion, the wait time, and one of the processing temperature and the processing time of one of the plurality of fabrication steps.

In an example, the fabrication step with the wafer flatness requirement is performed after formation of contact structures and word line contacts.

In an example, the structures include contact structures and word line contacts, and the lithography process patterns the contact structures and the word line contacts.

Aspects of the disclosure provide a method for a semiconductor device. The method can include obtaining a first wafer expansion of a first wafer that is collected along a first direction parallel to a working surface of the first wafer during a lithography process for patterning structures of the semiconductor device on the working surface of the first wafer. Before a bonding step with a wafer flatness requirement, a wafer flatness of the first wafer can be determined based on the first wafer expansion using a flatness prediction model that is configured to predict the wafer flatness. The method further includes depositing a layer on a back side of the first wafer with a thickness that is determined based on the determined wafer flatness of the first wafer and bonding, face to face, the first wafer with a second wafer.

In an embodiment, the wafer flatness of the first wafer after depositing the layer satisfies the wafer flatness requirement.

In an embodiment, the method further includes measuring a second wafer expansion along a second direction parallel to the working surface of the first wafer. The first direction can be perpendicular to the second direction. The wafer flatness of the first wafer can be determined based on the first wafer expansion and the second wafer expansion using the flatness prediction model.

In an embodiment, the method further includes, after the lithography process and prior to the determining step, modifying the first wafer by forming the structures on the working surface of the first wafer using a plurality of fabrication steps. The wafer flatness of the first wafer can be determined based on the first wafer expansion and a wait time between two of the plurality of fabrication steps using the flatness prediction model configured to predict the wafer flatness.

In an embodiment, the wafer flatness is indicated by a bow of the first wafer, the flatness prediction model is a bow prediction model. The bow of the first wafer can be determined based on the first wafer expansion using the bow prediction model that predicts the bow of the first wafer.

In an embodiment, the flatness prediction model is based on a machine learning algorithm. The method further includes measuring a wafer expansion of a third wafer along a direction that is parallel to the working surface of the third wafer during a lithography process for patterning structures on the working surface of the third wafer. Before the bonding step with a wafer flatness requirement is performed on the third wafer, a wafer flatness of the third wafer can be determined using the flatness prediction model. The method includes measuring an actual wafer flatness of the third wafer, and updating the flatness prediction model based on the measured wafer flatness of the third wafer and the determined wafer flatness of the third wafer.

In an embodiment, the method includes depositing a layer on a back side of the third wafer with a thickness that is based on the determined wafer flatness of the third wafer.

In an example, the method includes determining the wafer flatness of the first wafer based on a processing temperature or a processing time of one of the plurality of fabrication steps using the flatness prediction model. The flatness prediction model can be dependent on the first wafer expansion, the wait time, and one of the processing temperature and the processing time of one of the plurality of fabrication steps.

In an example, the semiconductor device is a semiconductor memory device including a 3D NAND array, the first wafer includes a plurality of 3D NAND arrays, and the second wafer includes peripheral circuitry to control the 3D NAND array.

In an example, the bonding step with the wafer flatness requirement is performed after formation of contact structures and word line contacts.

In an example, the structures include contact structures and word line contacts, and the lithography process patterns the contact structures and the word line contacts.

In an example, the structures of the semiconductor device include channel structures of a 3D NAND array. Based on the first wafer expansion, the wafer flatness of the first wafer can be determined using the flatness prediction model prior to fabricating word line contacts of the semiconductor device and after the formation of the channel structures of the 3D NAND array.

In an example, the lithography process is a lithography process that is performed closest in time to the fabrication step with the wafer flatness requirement.

Aspects of the disclosure provide computing apparatus. The computing apparatus can include processing circuitry that is configured to store a wafer expansion of a wafer that is collected along a first direction parallel to a working surface of the wafer during a lithography process for patterning structures on the working surface of the wafer. Before a fabrication step with a wafer flatness requirement, the processing circuitry can determine a wafer flatness of the wafer based on the wafer expansion collected during the lithography process using a flatness prediction model that is configured to predict the wafer flatness.

Aspects of the disclosure provide a non-transitory computer-readable storage medium storing a program executable by one or more processors to perform storing a wafer expansion of a wafer that is collected along a first direction parallel to a working surface of the wafer during a lithography process for forming structures on the working surface of the wafer. The a program executable by one or more processors can perform, before a fabrication step with a wafer flatness requirement, determining a wafer flatness of the wafer based on the wafer expansion collected during the lithography process using a flatness prediction model that is configured to predict the wafer flatness.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B show examples of different types of stress according to aspects of the disclosure.

FIG. 2 shows a variation of wafer flatness across a wafer according to an embodiment of the disclosure.

FIG. 3 shows a relationship between a bow of a wafer and a radius of curvature of the wafer according to an embodiment of the disclosure.

FIGS. 4A-4C show a relationship between a bow of a wafer and a wafer expansion according to an embodiment of the disclosure.

FIG. 5 shows a cross-sectional view of a semiconductor device during a fabrication process in accordance with some embodiments.

FIG. 6 shows a flow chart outlining a process for forming a semiconductor device according to some embodiments of the disclosure.

FIG. 7 shows a flow chart outlining a process for determining wafer flatness according to some embodiments of the disclosure.

FIGS. 8-13 show cross-sectional views of a semiconductor device during a fabrication process in accordance with some embodiments.

FIGS. 14A-14D show exemplary relationships between wafer expansions of wafers measured at a first time and respective wafer flatness of the wafers measured at a second time according to an embodiment of the disclosure.

FIGS. 15A-15B show an exemplary relationship between a wafer expansion of a wafer measured at a first time and a wafer flatness of the wafer measured at a second time based on a queue time according to an embodiment of the disclosure.

FIG. 15C shows a relationship between a wafer flatness and a queue time according to an embodiment of the disclosure.

FIG. 15D shows an exemplary relationship between a wafer expansion of a wafer measured at a first time and a wafer flatness of the wafer measured at a second time based on a queue time according to an embodiment of the disclosure.

FIG. 16 shows an exemplary comparison of actual measured bow and predicted bow according to an embodiment of the disclosure.

FIG. 17 shows an exemplary linear relationship of actual measured bow and predicted bow according to an embodiment of the disclosure.

FIG. 18 shows a computer system (1800) suitable for implementing certain embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Semiconductor circuit components can be formed on a wafer in a fabrication process. The fabrication process can include various fabrication steps (or stages). Aspects of the disclosure provide techniques for determining wafer flatness of the wafer using a flatness prediction model. At least one wafer expansion of a wafer can be stored. For example, the at least one wafer expansion can be collected during a lithography process for patterning structures on a working surface of the wafer in the fabrication process. Before a fabrication step with a wafer flatness requirement is performed, a wafer flatness of the wafer can be determined based on the at least one wafer expansion using the flatness prediction model that predicts the wafer flatness based at least on the wafer expansion. As the techniques to determine the wafer flatness do not require an actual flatness measurement on the wafer using a flatness measurement station, the fabrication process is not interrupted and productivity can increase. For example, one or more measurements collected for the lithography process can also be reused to determine the wafer flatness. In other embodiments, the measurements can be collected outside the lithography process.

The flatness of the wafer can change, for example, as the fabrication steps are performed on the wafer. In an example, based on the at least one expansion at an earlier stage of the fabrication process, such as when the lithography process is performed, the wafer flatness of the wafer at a later stage of the fabrication process can be determined using the flatness prediction model. As a plurality of fabrication steps may be performed on the wafer between the earlier and later stages, additional parameters may be included in the flatness prediction model for a more accurate prediction. For example, the flatness prediction model determines the wafer flatness further based on a wait time during which the wafer waits to be processed between two of the plurality of fabrication steps. In an example, the flatness prediction model determines the wafer flatness further based on a process parameter (e.g., a process temperature, a process time) of one of the plurality of fabrication steps.

In an example, the flatness prediction model is a bow prediction model that predicts a bow of the wafer based on the at least one wafer expansion. The flatness prediction model can be based on a machine learning algorithm and updated based on an actual measured wafer flatness and a predicted wafer flatness of a wafer. As wafer flatness of a majority of wafers do not need to be measured, a number of flatness measurement stations is significantly reduced, making the techniques cost-effective.

A layer can be deposited on a back side of the wafer with a thickness that is based on the predicted wafer flatness of the wafer. Subsequently, the wafer can be bonded with another wafer, face to face. In an example, the wafer includes a plurality of memory cell arrays, and the other wafer includes peripheral circuitry to control the memory cell arrays. The wafer can be fabricated to optimize density and performance of the memory cell arrays without compromising to fabrication limitations due to the periphery circuitry; and the other wafer can be fabricated to optimize the performance of the periphery circuitry without compromising to fabrication limitations due to the memory cell array.

Wafer flatness (or flatness) of a wafer, such as a semiconductor wafer, can indicate whether the wafer is flat. The wafer flatness can affect a device fabrication process including, for example, etching, bonding, lithography, and deposition, and thus a product yield. Flatness of the wafer can deviate due to various fabrication steps, such as depositions and/or etchings, used in forming a semiconductor device over the wafer.

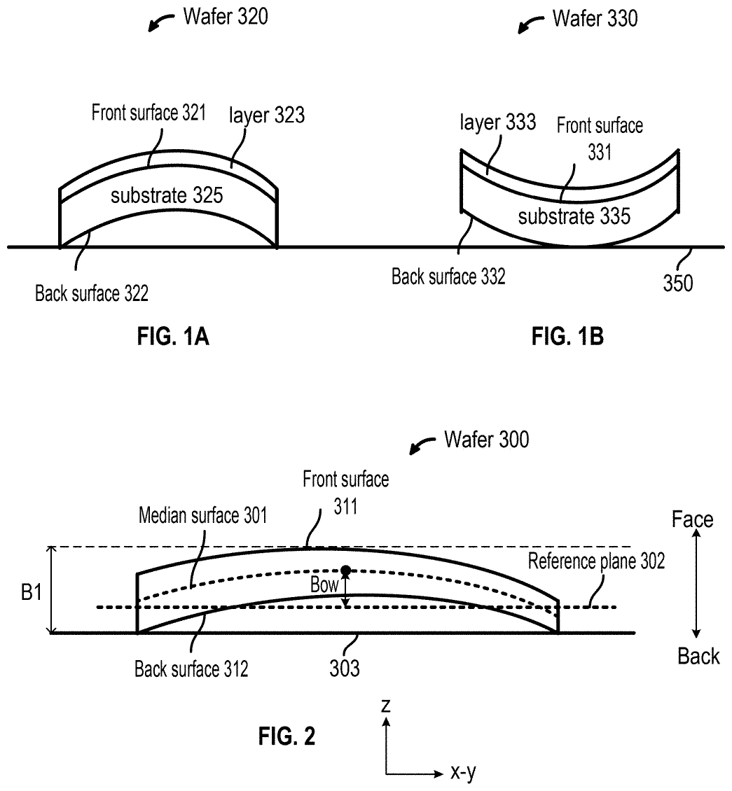

Typically, a layer (or film) deposition on a wafer can cause stress, and bending (or bowing) of the wafer. FIGS. 1A-1B show examples of wafer bowing according to an embodiment of the disclosure. Referring to FIG. 1A, a wafer 320 includes a layer (e.g., a thin film) 323 formed over a substrate 325. A deposition of the layer 323 can cause stress, and thus a middle region of the wafer 320 can move upwards and edges of the wafer 320 can bend (or bow) downwards with respect to a reference plane 350. Referring to FIG. 1B, a wafer 330 includes a layer (e.g., a thin film) 333 formed over a substrate 335. A deposition of the layer 333 can cause stress opposite to that in FIG. 1A, and thus a middle region of the wafer 330 can move downwards and edges of the wafer 330 can bend (or bow) upwards with respect to the reference plane 350. Such upward or downward bending or bowing of a wafer can be characterized using a parameter, such as a wafer bow (or a bow) of the wafer, as described below.

FIG. 2 shows a variation of wafer flatness across a wafer 300 according to an embodiment of the disclosure. The wafer 300 can include a front surface 311 on a face side and a back surface 312 on a back side. In an example, semiconductor device(s) can be fabricated over the front surface (or a working surface) 311 on the face side.

The flatness of the wafer 300 can be described using any suitable parameter with respect to a reference plane (e.g., a reference plane 302) and measured using any suitable method. The reference plane can be chosen in any suitable different way, depending on how the flatness is characterized. The reference plane can be chosen to include three points at specified locations, for example, on the front surface 311, on a median surface 301 that is between the front surface 311 and the back surface 312, on a least square fit to the median surface 301, on the back surface 312, on a least square fit to the back surface 312, or the like. In an example, the reference plane can be a plane of a sample holder of a metrology tool or a processing tool, such as a reference plane 303.

Referring to FIG. 2, in various examples, wafer flatness can be described using a wafer bow (or a bow) of the wafer 300. For example, the wafer bow of the wafer 300 can be described as a distance between a point B and a reference plane 302. The point B can be located at a mid-thickness (along a Z direction that is perpendicular to the reference plane 302) and at a wafer center (within an X-Y plane that is parallel to the reference plane 302) of the wafer 300. In an example, the reference plane 302 is the least square fit to the median surface 301. Though a specific distance is used to indicate the wafer bow, the wafer bow can be indicated by any other distance, such as a distance B1 in FIG. 2.

Different types of stress such as shown in FIGS. 1A-1B can be indicated using a sign of the wafer bow. In an example, a negative bow indicates a stress in FIG. 1A, and a positive bow corresponds to a stress in FIG. 1B.

As described above, wafer flatness can be characterized or defined using any suitable parameter including a wafer bow. For purposes of brevity, the descriptions below use a wafer bow of a wafer to represent the wafer flatness. However, the methods and embodiments in the disclosure are applicable to other scenarios where the wafer flatness is described using other parameters, such as warp. The descriptions for the methods and embodiments in the disclosure can be suitably adapted when other parameters are used to describe the wafer flatness.

In general, wafer flatness, such as a wafer bow, can be measured using any suitable method, such as noncontact measurement methods/apparatuses including noncontact electrical method with capacitance measurements, noncontact optical methods, or the like. The optical methods can include light interferometry, optical critical dimension (OCD) measurement, or the like. In some examples, an optical method uses a patterned wafer geometry (PWG) metrology tool.

As described, a bow of a wafer can affect a device fabrication process and a product yield, and thus the bow can be measured at one or more steps or stages when forming a semiconductor device over the wafer. In some examples, forming a semiconductor device can include wafer level bonding, such as bonding two wafers (e.g., a first wafer and a second wafer) face to face where a face side of the first wafer is bonded to a face side of a second wafer. Portions of the semiconductor device, including, for example, transistors can be fabricated over the face side of the first wafer and the face side of the second wafer, respectively. The two wafers should be flat (e.g., flatness, such as bows, of the two wafers satisfies a requirement) in order for bonding structures of the two wafers to align with each other.

In an example, a first wafer (e.g., an array wafer including three-dimensional (3D) NAND arrays) and a second wafer (e.g., a peripheral wafer including peripheral circuitry to control the 3D NAND arrays) are fabricated separately and then bonded face to face to form a semiconductor device (e.g., a semiconductor memory device). In general, the array wafer can have a relatively large bow due to fabrication steps, such as depositions and/or etchings. Thus, the bow of the array wafer may need to be compensated (or reduced) by any suitable bow compensation method or flattening method before the array wafer and the peripheral wafer are bonded together. In an example, a layer or a combination of layers (referred to as a compensation layer) is formed on a back side of the array wafer to flatten the array wafer. Properties of the layer including a layer thickness, material(s), and/or the like can be determined based on a bow (e.g., a magnitude and a sign) of the array wafer prior to the layer formation. In an example, a tensile stress is needed at the back side of the array wafer, and thus a silicon nitride layer can be deposited at the back side of the array wafer.

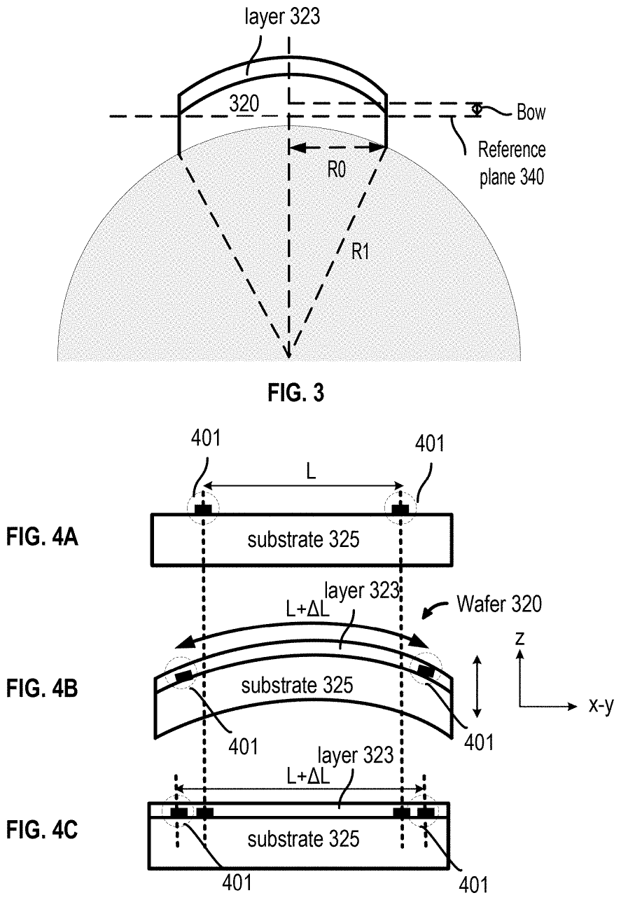

To reduce a wafer bow by a compensation method, the wafer bow is to be determined prior to performing the compensation method. Various methods can be used to determine the wafer bow. In an example, the wafer bow can be determined by measuring a radius of curvature of the wafer using any suitable measurement apparatus capable of measuring the radius of curvature. FIG. 3 shows a relationship between the bow of the wafer 320 and a radius of curvature R1 of the wafer 320 according to an embodiment of the disclosure. A curvature K is an inverse of the radius of curvature R1 of the wafer 320 (e.g., K=1/R1). A wafer radius is denoted as R0. The bow of the wafer 320 can depend on the curvature K and the wafer radius R0. Thus, the bow of the wafer 320 can be determined if the curvature K or the radius of curvature (1/K) is known. In an example, the bow of the wafer 320 is approximately proportional to the curvature K.

If a bow of each array wafer to be bonded is measured prior to bow compensation (or reduction) by a back-side deposition of a compensation layer, a large number of bow measurement apparatuses may be required as a number of wafers to be measured increases, and thus fabrication cost increases. Further, having a bow measurement for each wafer can interrupt a fabrication process, increase a fabrication time, and thus reduce productivity. Thus, methods that can avoid the need for such measurements, such as by predicting a wafer bow without measuring the actual bow and/or without interrupting the fabrication process of each wafer, can reduce fabrication time, increase productivity, and reduce fabrication cost.

Wafer flatness, such as indicated by a wafer bow (also referred to as an out-of-plane distortion) can be related to a wafer expansion (also referred to an in-plane distortion) within the X-Y plane. FIGS. 4A-4C show an exemplary relationship between a bow of the wafer 320 and a wafer expansion ΔL along a direction (e.g., an X direction, a Y direction, or another direction) within the X-Y plane.

FIG. 4A shows a first scenario where the wafer 320 includes the substrate 325 prior to the formation of the layer 323. Two structures 401 on the wafer 320 are separated along a direction (e.g., the X direction) by a distance L, and the bow of the wafer 320 is denoted as the first bow.

FIG. 4B shows a second scenario where the wafer 320 includes the substrate 325 and the layer 323, as described in FIG. 1A. The two structures 401 are separated further apart (larger than L), for example, due to stress caused by the deposition of the layer 323. The bow of the wafer 320 is denoted as the second bow.

FIG. 4C shows a distance L+ΔL between the two structures 401 along the direction for the second scenario. The wafer expansion ΔL along the direction can be related to the first bow of the wafer 320 and the second bow of the wafer 320. In an example, the wafer expansion ΔL is approximately proportional to a difference between the second bow and the first bow. As described above, a wafer bow is related to a radius of curvature of the wafer. Accordingly, the wafer expansion ΔL can be approximately proportional to a difference between a second radius of curvature of the wafer 320 in the second scenario and a first radius of curvature of the wafer 320 in the first scenario. If the first radius of curvature or the first bow is known or the first bow can be determined as minimal (e.g., considered as zero), the second radius of curvature and/or the second bow can be determined based on the wafer expansion ΔL.

In general, wafer expansion data (e.g., a wafer expansion along a direction within the X-Y plane) can be measured during a lithography process as a part of the fabrication process, thus no separate apparatuses and/or steps are needed to measure a wafer bow based on the wafer expansion data. Accordingly, fabrication cost can be reduced and productivity can be increased. After obtaining the wafer expansion data, the wafer bow can be derived based on the relationship between the wafer expansion and the wafer bow, such as described in FIGS. 4A-4C. The wafer expansion data can be collected in the same measurement used to perform the lithography or a separate measurement taken to derive the wafer bow.

Wafer flatness (e.g., the bow) of the wafer may be needed at a fabrication step or stage having a wafer flatness requirement. The fabrication step having such a wafer flatness requirement can include, for example, a bonding step (e.g., wafer level bonding), forming word line contacts, or the like. However, no wafer expansion data corresponding to the fabrication step is available, for example, when no lithography process is performed at the fabrication step. According to aspects of the disclosure, when fabricating a semiconductor device using a fabrication process including multiple fabrication steps, a wafer expansion (or wafer expansion data) can be measured at a first time (T1) (e.g., at a first fabrication step) of the fabrication process prior to predicting the flatness (or the bow) of the wafer at a second time (T2) (e.g., at a second fabrication step) of the fabrication process. The second time can occur later than the first time. The second time may be equal to the first time in certain embodiments. The wafer bow at the later time (e.g., the second time) can be predicted based on the wafer expansion data at the first time. The wafer expansion data can be measured using lithography for the first step.

In an example, in order for the wafer expansion measured at the first fabrication step to predict the wafer flatness (or the bow) at the second fabrication step accurately, the first fabrication step is chosen to be the closest fabrication step in time to the second fabrication step. Which fabrication step is selected as the first fabrication step where the wafer expansion is measured can be determined based on a device fabrication process and requirements. For example, a number of fabrication steps between the second fabrication step and the first fabrication step is minimized. In an example, there are no other lithography process between the first time (e.g., at the first fabrication step) and the second time (e.g., at the second fabrication step). In some examples, a structural change of the semiconductor device due to fabrication step(s) between the first time and the second time is relatively small, for example, a bow difference of a first bow at the first time (e.g., corresponding to the wafer expansion at the first time) and the bow at the second time is less than a threshold in order to accurately predict the wafer flatness.

In general, the flatness of the wafer at the time T2 can depend on flatness of the wafer (e.g., a wafer bow) at the time T1 and a change to the flatness, if any, caused by the fabrication step(s) performed on the wafer between the time T1 and the time T2. The time T2 can be larger than the time T1, and is a later time than T1.

According to aspects of the disclosure, a flatness prediction model can be configured to determine flatness (e.g., the bow) of the wafer at T2 based on flatness of the wafer at T1. The flatness of the wafer at T1 can be indicated, for example, by the wafer expansion measured at T1. The flatness prediction model can indicate a relationship between a flatness variable Fl (e.g., an output of the flatness prediction model) and one or more input variables (e.g., input(s) to the flatness prediction model). The flatness variable Fl can indicate the flatness of the wafer at T2. The one or more input variables can include any one or any suitable combination of (i) at least one expansion variable E (e.g., an X expansion variable Eₓ indicating an X expansion along the X direction, a Y expansion variable E_{y} indicating a Y expansion along the Y direction) that indicates the flatness at T1, (ii) at least one wait time (also referred to as queue time) variable Qₜᵢₘₑ₁ to Qₜᵢₘₑᵢ that are associated with the fabrication step(s) between T1 and T2, (iii) one or more process parameters (e.g., a process temperature, a process time, a process type) of the respective fabrication step(s), and/or the like. The integer i is positive indicating a number of the at least one wait time included in the flatness prediction model. Each of the at least one wait time (e.g., Qₜᵢₘₑ₁) is a wait time between two fabrication steps where the wafer is waiting to be processed.

As the change to the flatness between T1 and T2 can depend on the fabrication step(s) performed on the wafer between T1 and T2, each process may affect the flatness at T2. Accordingly, the flatness prediction model can be made more accurate by incorporating effects of process parameters associated with the fabrication step(s). One fabrication step can have a larger effect than another fabrication step. In an example, process parameters that have a relatively large impact on the flatness at T2 are incorporated into the flatness prediction model. The process parameters that have a relatively large impact on the flatness at T2 can include expansion data, wait time(s), and/or the like.

The one or more input variables can include multiple input variables. In an example, the multiple input variables include the at least one expansion variable and the at least one wait time variable. The flatness variable Fl can be written as a function f1 of the multiple input variables as Eq. 1, indicating that the flatness at T2 depends on the at least one wafer expansion at T1 and the at least one wait time.

Fl=f1(Eₓ,E_{y},Qₜᵢₘₑ₁, . . . Qₜᵢₘₑᵢ,) Eq. 1

In an example, the multiple input variables include the at least one expansion variable, the at least one queue time variable, and the one or more process parameters. The flatness variable Fl can be written as a function f2 of the multiple input variables as Eq. 2, where the integer J is positive indicating a number of the fabrication step(s) to be considered in the flatness prediction model. Tₑₘₚⱼ and Tj can represent a temperature and a processing duration of a jth process.

Fl=f2(Eₓ,E_{y},Qₜᵢₘₑ₁, . . . Qₜᵢₘₑᵢ,Tₑₘₚ₁,T1, . . . ,Tₑₘₚⱼ,Tⱼ) Eq. 2

In an example, the flatness variable Fl can be written as a function f3 of the multiple input variables as Eq. 3 where the at least one queue time is constrained to be within a smaller range. For example, a total range that is available to one of the at least one queue time variable is 3-12 hours. Using Eq. 3, a subrange (e.g., 4 to 5 hours) of the total range (e.g., 3-12 hours) is chosen.

Fl=f3(Eₓ,E_{y},Qₜᵢₘₑ₁ being in a first range, . . . ,Qₜᵢₘₑᵢ being in an ith range, . . . ) Eq. 3

In an example, the multiple input variables include multiple expansion variables, such as the X expansion variable and the Y expansion variable. The flatness variable Fl can be written as a function f4 of the multiple input variables as Eq. 4.

Fl=f4(Eₓ,E_{y}) Eq. 4

In an example, the one or more input variables include an expansion variable (e.g., Eₓ or E_{y}). The flatness variable Fl can be written as a function f5 of the expansion variable as Eq. 5.

Fl=f5(Eₓ) Eq. 5

In general, the time T2 can be larger than the time T1, and is a later time than T1. Eqs. 1-5 can be used to determine the flatness at T2 based on the respective expansion data collected at T1. In an example, the time T2 is the time T1 and Eq. 4 or Eq. 5 can be used to determine the flatness at T1 based on the respective expansion data collected at T1.

In various examples, for the flatness prediction model including the one or more input variables, such as shown in Eqs. 1-5, the flatness prediction model can determine the flatness based on input(s) to a subset or a complete set of the one or more input variables. For example, the flatness can be determined using the flatness prediction model in Eq. 1 based on input(s) to one or more of Eₓ, E_{y}, Qₜᵢₘₑ₁, . . . , Qₜᵢₘₑ. In an example, the flatness can be determined using the flatness prediction model in Eq. 1 based on the X expansion.

According to aspects of the disclosure, a method for determining wafer flatness (e.g., a bow of a wafer) is described, for example, for a first wafer. At least one wafer expansion (or expansion data) (e.g., an X expansion and/or a Y expansion) of the first wafer that is collected during a lithography process for patterning structures on a working surface of the first wafer can be stored. The at least one wafer expansion can be measured along one or more directions that are parallel to the working surface of the first wafer during the lithography process. For example, the one or more directions are within the X-Y plane shown in FIG. 2. Before a fabrication step with a wafer flatness requirement is performed, a wafer flatness of the first wafer can be determined based on the at least one wafer expansion using a flatness prediction model that predicts the wafer flatness, such as described above using Eqs. 1-5.

In an example, after the lithography process and prior to the determination of the flatness using the flatness prediction model, the first wafer can be modified using a plurality of fabrication steps that includes forming the structures. The wafer flatness can be determined based on the at least one wafer expansion and a wait time (e.g., Qₜᵢₘₑ₁) between two of the plurality of processes using the flatness prediction model, such as shown in Eqs. 1-3.

The flatness prediction model can be updated (e.g., optimized) using any suitable machine learning algorithm, for example, to determine the flatness of the wafer with a higher accuracy. For example, in addition to predicting the flatness (referred to as a virtual measurement) using the flatness prediction model, actual flatness of a subset (e.g., 10%) of wafers to be predicted is measured directly, and thus resulting in actually measured flatness of the subset of wafers. The flatness prediction model can be updated using a machine learning algorithm based on the actually measured flatness of the subset of wafers and the predicted flatness of the subset of wafers. The flatness prediction model can be updated, for example, continuously as actual flatness of additional wafers and predicted flatness of the additional wafers are available.

The benefit of the flatness prediction method includes a significant reduction of actual flatness measurements, for example, a 90% reduction in a number of wafers whose flatness is measured, and thus a significant reduction in a number of measurement apparatuses for measuring the actual flatness and a higher productivity as measurement time used in the flatness measurements is reduced. Thus, the flatness prediction method including a combination of virtual measurements on a plurality of wafers and selective measurements on a small subset (e.g., 80-90%) of the plurality of wafers can be suitable for mass production.

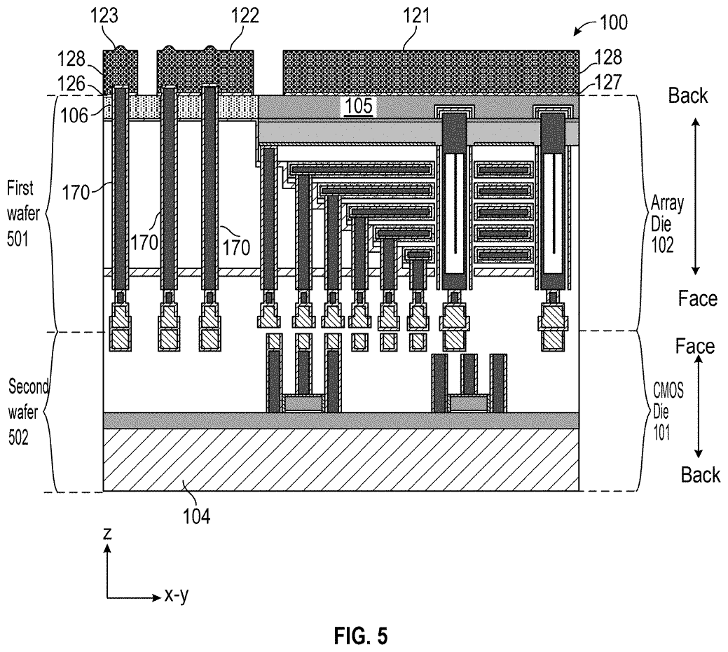

Prior to describing the flatness prediction method in detail, an example of a semiconductor device (e.g., a semiconductor memory device 100 in FIG. 5) is described below. The semiconductor device is fabricated on a wafer based on a wafer flatness that is determined using the flatness prediction method.

FIG. 5 shows a cross-sectional view of a semiconductor device, such as the semiconductor memory device 100, according to some embodiments of the disclosure. The semiconductor memory device 100 can be formed using wafer level bonding that bonds a first wafer 501 and a second wafer 502. The wafer level bonding results in a bonding of two dies face to face. In an example, the semiconductor memory device 100 includes the two dies bonded face to face.

Specifically, in the FIG. 5 example, the semiconductor device 100 (or the semiconductor memory device 100) includes an array die 102 and a CMOS die 101 bonded face to face. It is noted that, in some embodiments, a semiconductor memory device can include multiple array dies and a CMOS die. The multiple array dies and the CMOS die can be stacked and bonded together. The CMOS die is respectively coupled to the multiple array dies, and can drive the respective array dies in a similar manner.

The semiconductor device 100 can be any suitable device. In some examples, the semiconductor device 100 includes the first wafer 501 and the second wafer 502 bonded face to face. The array die 102 is disposed with other array dies on the first wafer 501, and the CMOS die 101, for example, including a peripheral circuit, is disposed with other CMOS dies on the second wafer 502. The first wafer 501 and the second wafer 502 are bonded together, thus the array dies on the first wafer 501 are bonded with corresponding CMOS dies on the second wafer 502. In some examples, the semiconductor device 100 is a semiconductor chip with at least the array die 102 and the CMOS die 101 bonded together. In an example, the semiconductor chip is diced from wafers (e.g., the first wafer 501 and the second wafer 502) that are bonded together. In another example, the semiconductor device 100 is a semiconductor package that includes one or more semiconductor chips assembled on a package substrate.

The array die 102 includes one or more semiconductor portions 105, and insulating portions 106 between the semiconductor portions 105. The memory cell arrays can be formed in the semiconductor portions 105, the insulating portions can isolate the semiconductor portions 105 and provide space for contact structures 170. The CMOS die 101 includes a substrate 104, and peripheral circuitry formed on the substrate 104. For simplicity, a main surface (of the dies or wafers) is referred to as an X-Y plane, and a direction perpendicular to the main surface is referred to as a Z direction.

Further, in the FIG. 5 example, connection structures 121 and pad structures 122-123 are formed on a back side of one of the two dies, such as the array die 102. Specifically, in the FIG. 5 example, the pad structures 122-123 are above the insulating portions 106 and each of the pad structures 122-123 can be conductively connected with one or more of the contact structures 170. In the FIG. 5 example, a connection structure 121 is above the semiconductor portion 105 and is conductively connected to the semiconductor portion 105. In some examples, the semiconductor portion 105 is coupled to an array common source (ACS) for a memory cell array, and the connection structure 121 is disposed over semiconductor portion(s) 105 for a block of memory cell arrays. In some example, the connection structure 121 is formed of metal layers of relatively low resistivity, and when the connection structure 121 covers a relatively large portion of the semiconductor portion 105, the connection structure 121 can connect the ACS of the block of the memory cell arrays with very small parasitic resistance. The connection structure 121 can include a portion that is configured as a pad structure for ACS to receive ACS signal from an external source. The pad structures 122-123 and the connection structure 121 are made of suitable metal material(s), such as aluminum, and the like that can facilitate attachment of bonding wires. In some examples, the pad structures 122-123 include a titanium layer 126 and an aluminum layer 128, and the connection structure 121 includes a titanium silicide layer 127 and the aluminum layer 128.

For ease of illustration, some components of the semiconductor memory device 100, such as passivation structures, and the like are not shown.

The array die 102 initially includes a substrate and semiconductor portions 105 and the insulating portions 106 are formed on the substrate. The substrate is removed before the formation the pad structures 122-123 and the connection structure 121.

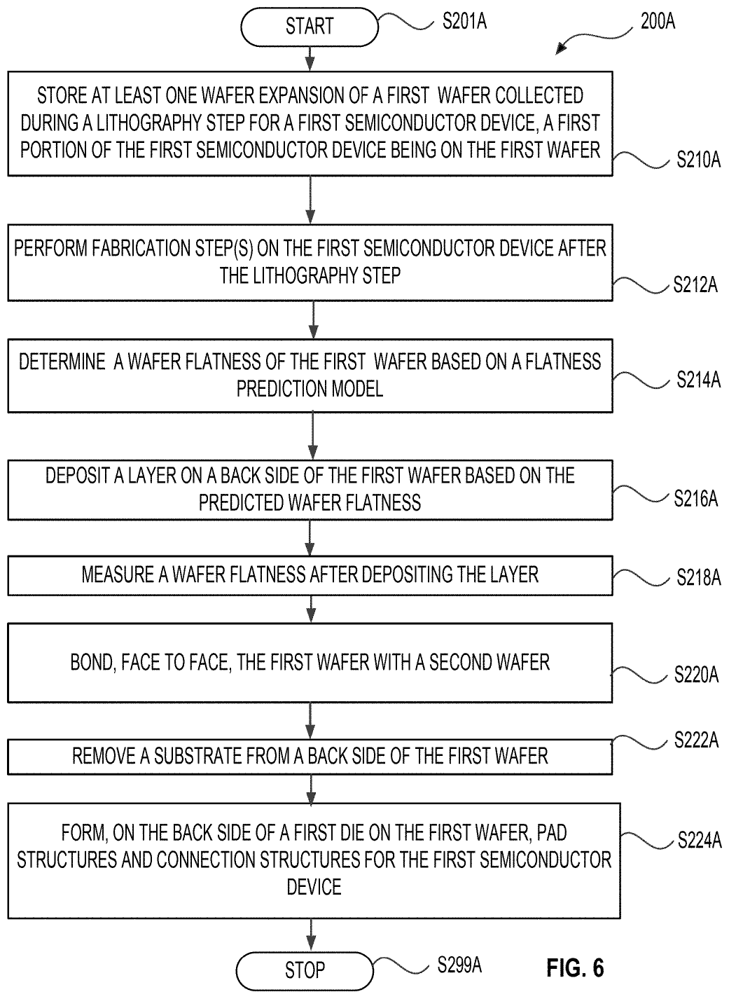

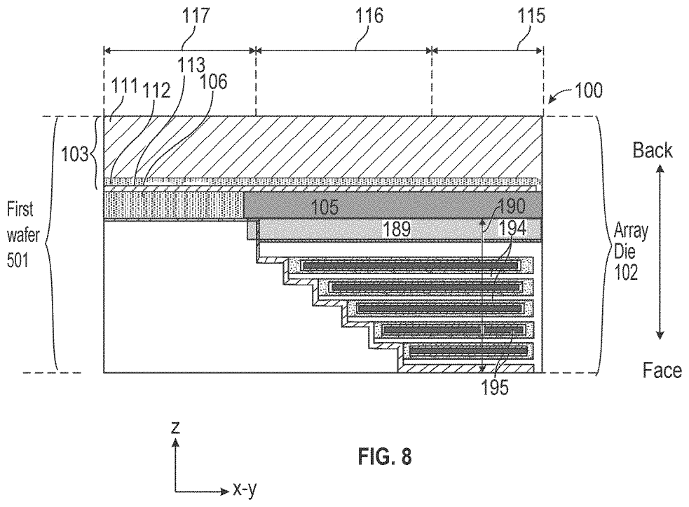

FIG. 6 shows a flow chart outlining a process 200A for forming a first semiconductor device, such as the semiconductor memory device 100 according to some embodiments of the disclosure, and FIGS. 8-13 show cross-sectional views of the semiconductor memory device 100 during the process in accordance with some embodiments. The process 200A can include predicting wafer flatness using the flatness prediction model such as described above. The process 200A starts from S201A and proceeds to S210A.

At S210A, at least one wafer expansion of a first wafer collected during a lithography process for the first semiconductor device (e.g., the semiconductor memory device 100) can be stored. As described below at a step S214A, the at least one wafer expansion of the first wafer collected during the lithography process can be used to predict a wafer flatness (or a bow) at another fabrication step (e.g., a second fabrication step or at a second time T2) with a wafer flatness requirement. For a manufacturing process having multiple lithography process, the lithography process where the wafer expansion is measured can be determined based on a device fabrication process and requirements. In an example, to predict the wafer flatness at the second fabrication step or at the second time (e.g., T2) accurately, the lithography process is chosen to be the closest lithography process in time from the second fabrication step, and thus there is no other lithography process between the lithography process and the second fabrication step.

In an example, the at least one wafer expansion of the first wafer is measured during the lithography process. The lithography process can include alignment, exposure, inspection, and/or the like. In an example, the lithography process includes metrology after exposing and developing photoresist. The at least one wafer expansion of the first wafer can be measured prior to or after the exposure, for example, during the alignment. In an example, the at least one wafer expansion of the first wafer is measured during the metrology.

FIG. 8 shows a cross-sectional view of the semiconductor memory device 100 at the lithography process, for example, prior to the formation of vertical memory cell strings. The semiconductor memory device 100 includes the array die 102. In some embodiments, the array die 102 is fabricated with other array dies on the first wafer 501.

The array die 102 includes a substrate 103. On the substrate 103, one or more semiconductor portions 105 and insulating portions 106 are formed. The insulating portions 106 are formed of insulating material, such as silicon oxide and the like that can insulate the semiconductor portions 105. In an example, memory cell arrays are to be formed in the semiconductor portions 105 and contact structures are to be formed in the insulating portions 106.

The substrate 103 can be any suitable substrate, such as a silicon (Si) substrate, a germanium (Ge) substrate, a silicon-germanium (SiGe) substrate, and/or a silicon-on-insulator (SOI) substrate. The substrate 103 may include a semiconductor material, for example, a Group IV semiconductor, a Group III-V compound semiconductor, or a Group II-VI oxide semiconductor. The Group IV semiconductor may include Si, Ge, or SiGe. The substrate 103 may be a bulk wafer or an epitaxial layer. In some examples, a substrate is formed of multiple layers. For example, the substrate 103 includes multiple layers, such as a bulk portion 111, a silicon oxide layer 112 and a silicon nitride layer 113, as shown in FIG. 8.

In some examples, the semiconductor portion 105 is formed on the substrate 103, and a block of 3D NAND memory cell strings are to be formed in the semiconductor portion 105. The semiconductor portion 105 is conductively coupled with an array common source of the memory cell strings. In some examples, a memory cell array is to be formed in a core region 115 as an array of vertical memory cell strings. Besides the core region 115, the array die 102 includes a staircase region 116 and an insulating region 117. The staircase region 116 is used to facilitate making connections to, for example, gates of the memory cells in the vertical memory cell strings, gates of the select transistors, and the like. The gates of the memory cells in the vertical memory cell strings correspond to word lines for the NAND memory architecture. The insulating region 117 is used to form the insulating portion 106.

A stack of layers 190 includes gate layers 195 and insulating layers 194 that are stacked alternatingly. The gate layers 195 and the insulating layers 194 are configured to form transistors that are stacked vertically. In some examples, the stack of transistors includes memory cells and select transistors, such as one or more bottom select transistors, one or more top select transistors and the like. In some examples, the stack of transistors can include one or more dummy select transistors. The gate layers 195 correspond to gates of the transistors. The gate layers 195 are made of gate stack materials, such as high dielectric constant (high-k) gate insulator layers, metal gate (MG) electrode, and the like. The insulating layers 194 are made of insulating material(s), such as silicon nitride, silicon dioxide, and the like.

In the FIG. 8 example, a common source layer 189 is formed and is to be conductively connected with a source of a vertical memory cell string. The common source layer 189 can includes one or more layers. In some examples, the common source layer 189 includes silicon material, such as intrinsic polysilicon, doped polysilicon (such as N-type doped silicon, P-type doped silicon and the like) and the like. In some examples, the common source layer 189 may include metal silicide to improve conductivity.

According to some aspects of the disclosure, the semiconductor portion 105 and the common source layer 189 are conductively coupled in some examples, thus the semiconductor portion 105 can be configured as an array common source for the vertical memory cell strings formed in the semiconductor portion 105.

A first portion of the first semiconductor device can be disposed on the face side of the first wafer, for example, over a working surface. In some embodiments, the first semiconductor device is the semiconductor memory device 100, and the first wafer is the first wafer 501. In an example, referring to FIG. 8, the first portion of the first semiconductor device (e.g., the semiconductor memory device 100) includes the semiconductor portion 105, the common source layer 189, and the stack of layers 190 formed over the substrate 103. The lithography process can be performed on the semiconductor memory device 100 shown in FIG. 8. For purposes of clarity, a mask layer over the first wafer 501 used in the lithography process is not shown.

The at least one wafer expansion of the first wafer 501 can be measured during the lithography process, and a time when the lithography process is performed is referred to as the first time (e.g., T1). The at least one wafer expansion of the first wafer 501 can include one or more wafer expansions along respective one or more directions within the X-Y plane (e.g., parallel to the working surface of the first wafer), such as an X wafer expansion along the X direction and/or a Y wafer expansion along the Y direction. In an example, the X direction is perpendicular to the Y direction.

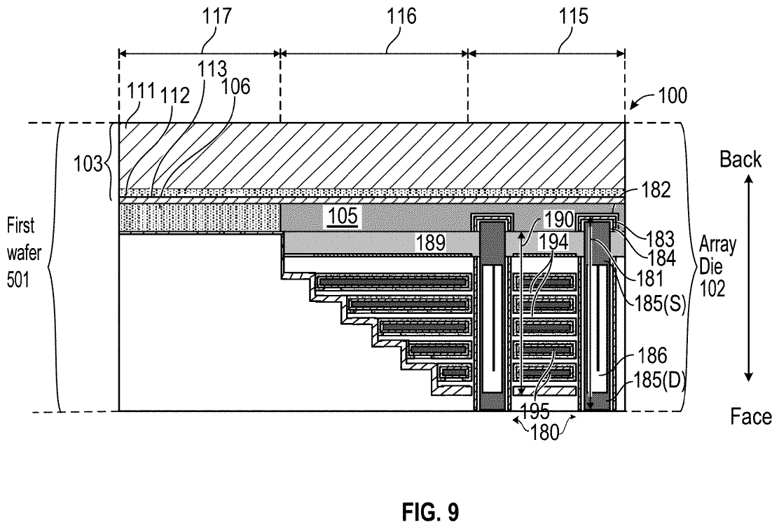

At S212A, fabrication step(s) can be performed on the first semiconductor device after the lithography process. In an example, a second portion (e.g., vertical memory cell strings 180 in FIG. 9) of the first semiconductor device can be formed on the first wafer after the lithography process. In an example, certain structures and/or materials are removed from the first semiconductor device.

In an example, referring to FIG. 9, the fabrication step(s) include forming the vertical memory cell strings 180. The lithography process is for a fabrication step that patterns structures on the face side of the first wafer. For example, a pattern of channel holes disposed in the X-Y plane can be formed after the lithography process.

The fabrication step(s) include forming the vertical memory cell strings 180 including the channel structures 181. As the fabrication step(s) include etching(s), multiple depositions of different materials, and the like, the first wafer 501 can be in queue(s) between the etching(s) and the multiple depositions and wait to be processed. Thus, the first wafer 501 can experience at least one wait time in the fabrication step(s). A queue time between two of the plurality of fabrication step(s) can be any suitable duration, such as on an order of magnitude of an hour, such as from 3 to 12 hours.

Referring to FIG. 9, in some examples, the vertical memory cell strings 180 can be formed in the semiconductor portion 105. The semiconductor portion 105 is conductively coupled with an array common source of the memory cell strings 180. In some examples, a memory cell array is formed in a core region 115 as an array of vertical memory cell strings.

In the FIG. 9 example, the vertical memory cell strings 180 are shown as representation of an array of vertical memory cell strings formed in the core region 115. The vertical memory cell strings 180 are formed in the stack of layers 190.

According to some aspects of the disclosure, the vertical memory cell strings are formed of the channel structures 181 that extend vertically (Z direction) into the stack of layers 190. The channel structures 181 can be disposed separately from each other in the X-Y plane. In some embodiments, the channel structures 181 are disposed in the form of arrays between gate line cut structures (not shown). The gate line cut structures are used to facilitate replacement of sacrificial layers with the gate layers 195 in a gate-last process. The arrays of the channel structures 181 can have any suitable array shape, such as a matrix array shape along the X direction and the Y direction, a zig-zag array shape along the X or Y direction, a beehive (e.g., hexagonal) array shape, and the like. In some embodiments, each of the channel structures has a circular shape in the X-Y plane, and a pillar shape in the X-Z plane and Y-Z plane. In some embodiments, the quantity and arrangement of the channel structures between gate line cut structures is not limited.

In some embodiments, the channel structure 181 has a pillar shape that extends in the Z direction that is perpendicular to the direction of the main surface of the substrate 103. In an embodiment, the channel structure 181 is formed by materials in the circular shape in the X-Y plane, and extends in the Z direction. For example, the channel structure 181 includes function layers, such as a blocking insulating layer 182 (e.g., silicon oxide), a charge storage layer (e.g., silicon nitride) 183, a tunneling insulating layer 184 (e.g., silicon oxide), a semiconductor layer 185, and an insulating layer 186 that have the circular shape in the X-Y plane, and extend in the Z direction. In an example, the blocking insulating layer 182 (e.g., silicon oxide) is formed on the sidewall of a hole (into the stack of layers 190) for the channel structure 181, and then the charge storage layer (e.g., silicon nitride) 183, the tunneling insulating layer 184, the semiconductor layer 185, and the insulating layer 186 are sequentially stacked from the sidewall. The semiconductor layer 185 can be any suitable semiconductor material, such as polysilicon or monocrystalline silicon, and the semiconductor material may be un-doped or may include a p-type or n-type dopant. In some examples, the semiconductor material is intrinsic silicon material that is un-doped. However due to defects, intrinsic silicon material can have a carrier density in the order of 10¹⁰ cm⁻³ in some examples. The insulating layer 186 is formed of an insulating material, such as silicon oxide and/or silicon nitride, and/or may be formed as an air gap.

According to some aspects of the disclosure, the channel structure 181 and the stack of layers 190 together form the memory cell string 180. For example, the semiconductor layer 185 corresponds to the channel portions for transistors in the memory cell string 180, and the gate layers 195 correspond to the gates of the transistors in the memory cells string 180. Generally, a transistor has a gate that controls a channel, and has a drain and a source at each side of the channel. For simplicity, in the FIG. 9 example, the bottom side of the channel for transistors in FIG. 3 is referred to as the drain, and the upper side of the channel for transistors in FIG. 9 is referred to as the source. The drain and the source can be switched under certain driving configurations. In the FIG. 9 example, the semiconductor layer 185 corresponds to connected channels of the transistors. For a specific transistor, the drain of the specific transistor is connected with a source of a lower transistor below the specific transistor, and the source of the specific transistor is connected with a drain of an upper transistor above the specific transistor in the FIG. 9 example. Thus, the transistors in the memory cell string 180 are connected in series. “Upper” and “lower” are used specific to FIG. 9 where the array die 102 is disposed upside down.

The memory cell string 180 includes memory cell transistors (or referred to as memory cells). A memory cell transistor can have different threshold voltages based on carrier trappings in a portion of the charge storage layer 183 that corresponds to a floating gate for the memory cell transistor. For example, when a significant amount of holes are trapped (stored) in the floating gate of the memory cell transistor, the threshold voltage of the memory cell transistor is lower than a predefined value, then the memory cell transistor is in a un-programed state (also referred to as erased state) corresponding to logic “1”. When holes are expelled from the floating gate, the threshold voltage of the memory cell transistor is above a predefined value, thus the memory cell transistor is in a programed state corresponding to logic “0” in some examples.

The memory cell string 180 includes one or more top select transistors configured to couple/de-couple the memory cells in the memory cell string 180 to a bit line, and includes one or more bottom select transistors configured to couple/de-couple the memory cells in the memory cell string 180 to the ACS.

The top select transistors are controlled by top select gates (TSG). For example, when a TSG voltage (voltage applied to the TSG) is larger than a threshold voltage of the top select transistors, the top select transistors in the memory cell string 180 are turned on and the memory cells in the memory cell string 180 are coupled to the bit line (e.g., drain of the string of memory cells is coupled to the bit line); and when the TSG voltage (voltage applied to the TSG) is smaller than the threshold voltage of the top select transistors, the top select transistors are turned off and the memory cells in the memory cell string 180 are de-coupled from the bit line (e.g., drain of the string of memory cells is decoupled from the bit line).

Similarly, the bottom select transistors are controlled by bottom select gates (BSG). For example, when a BSG voltage (voltage applied to the BSG) is larger than a threshold voltage of the bottom select transistors in a memory cell string 180, the bottom select transistors are turned on and the memory cells in the memory cell string 180 are coupled to the ACS (e.g., source of the string of memory cells in the memory cell string 180 is coupled to the ACS); and when the BSG voltage (voltage applied to the BSG) is smaller than the threshold voltage of the bottom select transistors, the bottom select transistors are turned off and the memory cells are de-coupled from the ACS (e.g., source of the string of memory cells in the memory cell string 180 is de-coupled from the ACS).

Shown in FIG. 9, the upper portion of the semiconductor layer 185 in the channel hole corresponds to a source side of the vertical memory cell string 180, and the upper portion is labeled as 185(S). In the FIG. 9 example, the common source layer 189 is formed in conductive connection with the source of the vertical memory cell string 180. The common source layer 189 is similarly in conductive connection with sources of other vertical memory cell strings (not shown) in the semiconductor portion 105, and thus forms an array common source (ACS).

In the FIG. 9 example, in the channel structure 181, the semiconductor layer 185 extends vertically from the source side of the channel structure 181 down, and forms a bottom portion corresponds to a drain side of the vertical memory cell string 180. The bottom portion of the semiconductor layer 185 is labeled as 185(D). It is noted that drain side and the source side are named for the ease of description. The drain side and the source side may function differently from the names.

At S214A, a wafer flatness of the first wafer after the fabrication step(s) can be determined (or predicted) based on the flatness prediction model.

The wafer flatness of the first wafer 501 at the second time (e.g., T2) can be predicted. Referring to FIG. 9, the second time can be after the fabrication step(s), for example, after the vertical memory cell strings 180 and the gate layers 195 are formed. In an example, the second portion includes the vertical memory cell strings 180 and the gate layers 195. Referring to FIG. 11, in an example, the second time is also prior to the formation of the contact structures 170 and word line connection structure (also referred to as word line contacts) 150. The second time can also be prior to the formation of bonding structures 174 and 164.

In general, the flatness prediction model is configured to determine the wafer flatness of the first wafer based on one or more of the at least one expansion that indicates the flatness at the first time (e.g., T1), such as at the lithography process, (ii) the at least one wait time between the first time (e.g., T1) and the second time (e.g., T2), (iii) one or more process parameters (e.g., a process temperature, a process time) of the respective fabrication step(s), and/or the like, such as described in Eqs. 1-5.

Accordingly, input(s) to the flatness prediction model can include one or more of the at least one expansion, (ii) the at least one wait time between the first time and the second time, (iii) the one or more process parameters of the respective fabrication step(s), and/or the like. An output of the flatness prediction model can indicate the wafer flatness of the first wafer (e.g., the first wafer 501), such as the bow.

In an example, the wafer flatness is indicated by the bow of the first wafer, and the flatness prediction model is a bow prediction model that predicts the bow of the first wafer based on input(s) similar or identical to the input(s) to the flatness prediction model described above. The bow of the first wafer can be determined based on the bow prediction model.

In an example, the flatness prediction model is based on a machine learning algorithm and is updated based on measured wafer flatness and predicted wafer flatness of a third wafer. At least one wafer expansion of the third wafer can be measured during a lithography process for patterning structures on a face side of the third wafer. In an example, the at least one wafer expansion of the third wafer is measured at a third time. A wafer flatness of the third wafer can be determined using the flatness prediction model, for example, before a fabrication step with a wafer flatness requirement is performed. The flatness prediction model can be configured to determine the wafer flatness of the third wafer based on the at least one wafer expansion of the third wafer. In an example, the wafer flatness of the third wafer at a fourth time is predicted. Further, an actual wafer flatness of the third wafer can be measured before the fabrication step with the wafer flatness requirement for the third wafer, for example, at the fourth time. Generally, the flatness of the third wafer has minimal or no change between the actual measurement and the determination using the flatness prediction model. The flatness prediction model can be updated based on the measured wafer flatness of the third wafer and the predicted wafer flatness of the third wafer.

The updated flatness prediction model can be employed by other wafers where the flatness is to be predicted. In an example, the fourth time is later than the third time. In an example, the fourth time is the third time.

In an example, the third wafer is different from the first wafer, and no actual measurement is performed on the first wafer to determine the flatness of the first wafer at T2. The updated flatness prediction model can be employed to predict the flatness of the first wafer at T2.

In an example, the third wafer is the first wafer, and the above description can be adapted. The measurement of the at least one wafer expansion of the third wafer and the determination of the flatness of the third wafer using the flatness prediction model can be omitted.

At S216A, a layer can be deposited on a back side of the first wafer with a thickness that is based on the determined wafer flatness of the first wafer. In an example, the thickness is determined to adjust the wafer flatness for satisfying the wafer flatness requirement. In an example, the wafer flatness of the first wafer after depositing the layer satisfies the wafer flatness requirement. In an example described at S216A, the thickness of the layer is adjusted to satisfy the wafer flatness requirement. In general, one or more properties of the layer, such as the thickness, a material composition of the layer, a location of the layer, a process used to form the layer, and/or the like can be used to satisfy the wafer flatness requirement.

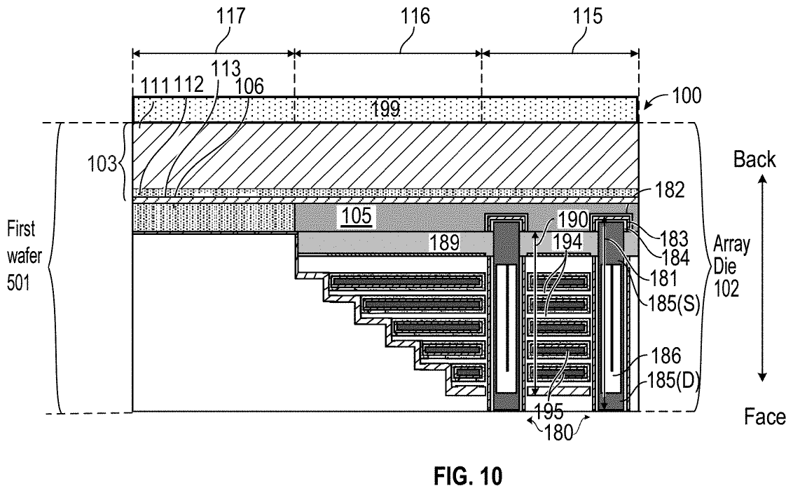

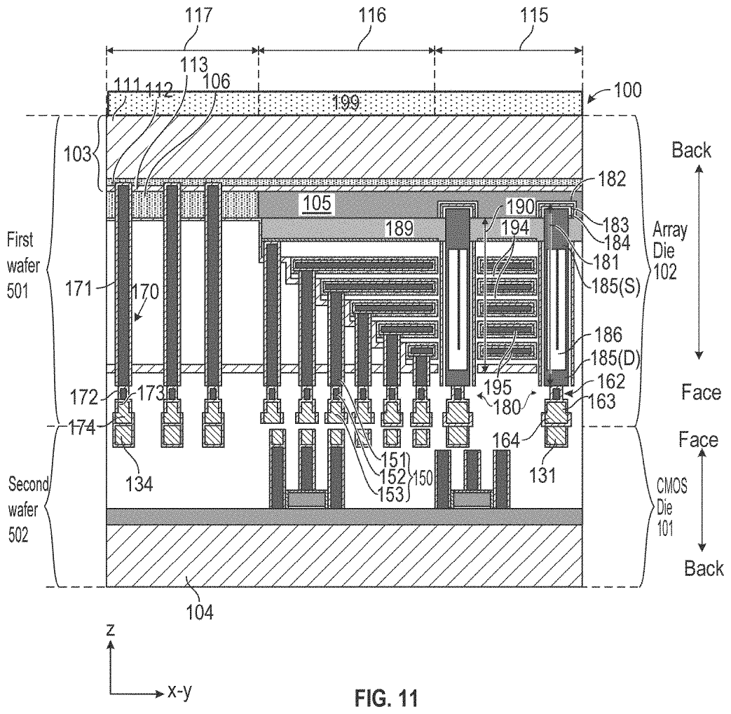

As described above with reference to FIGS. 1A-1B, in general, the predicted flatness or bow of the first wafer, such as the first wafer 501, can indicate a nature of stress (e.g., tensile stress or compressive stress) for the first wafer 501. In order to reduce the bow of the first wafer 501, the thickness of the layer can be determined based on a magnitude of the predicted bow. A material can be determined based on a nature of the stress (e.g., tensile stress or compressive stress) indicated by the predicted flatness and a location (e.g., the back side of the first wafer) where the layer is to be deposited. In an example, a material that generates tensile stress is to be deposited on the back side of the first wafer, and thus materials such as silicon nitride, polysilicon, tungsten or the like can be used. In an example, the layer can include silicon nitride. Referring to FIG. 10, the layer can be a silicon nitride layer 199 on the back side of the first array 501.

At S218A, a wafer flatness of the first wafer after depositing the layer can be measured, for example, by an optical critical dimension (OCD) measurement. In an example, S218A is omitted, and the wafer flatness of the first wafer after depositing the layer is not measured. If the measured wafer flatness (e.g., the measured bow) satisfies the wafer flatness requirement, the process 200A proceeds to S220A. Otherwise, the process 200A can either proceed to S299 and terminates or go back to S216A.

At S220A, the first wafer and a second wafer are bonded face to face. FIG. 11 shows a cross-sectional view of the semiconductor memory device 100 after the first wafer 501 is bonded to the second wafer 502 face to face. The semiconductor memory device 100 includes the array die 102 and the CMOS die 101 that are bonded face to face.

In some embodiments, the array die 102 is fabricated with other array dies on the first wafer 501, and the CMOS die 101 is fabricated with other CMOS dies on the second wafer 502. In some examples, the first wafer 501 and the second wafer 502 are fabricated separately. First bonding structures are formed on the face side of the first wafer 501. Similarly, periphery circuitry is formed on the second wafer 502 using processes that operate on the face side of the second wafer 502, and second bonding structures are formed on the face side of the second wafer 502.

In some embodiments, the first wafer 501 and the second wafer 502 can be bonded face to face using a wafer-to-wafer bonding technology. The first bonding structures on the first wafer 501 are bonded with corresponding second bonding structures on the second wafer 502, thus the array dies on the first wafer 501 are respectively bonded with the CMOS dies on the second wafer 502. In general, any suitable steps performed on the first wafer 501 can be performed on the second wafer to predict a wafer flatness (or a wafer bow) of the second wafer at a later fabrication step with a flatness requirement and subsequently compensate for the wafer bow. For example, steps S210A, S214A, S216A, and S218A are suitably adapted to store at least one wafer expansion measured at a lithography process, use the at least one wafer expansion to predict the wafer flatness of the second wafer at the later fabrication step, deposit a layer over the second wafer to satisfy the flatness requirement where one or more properties (e.g., a thickness of the layer) can be determined based on the predicted wafer flatness. Optionally, the wafer flatness after depositing the layer can be measured.

Further, contact structures can be formed in the insulating portions 106. The CMOS die 101 includes a substrate 104, and includes peripheral circuitry formed on the substrate 104. The substrate 104 can be similar or identical to the substrate 103, and thus detailed descriptions can be omitted for purposes of brevity.

In the FIG. 11 example, the memory cell arrays are formed on the substrate 103 of the array die 102 and the peripheral circuitry is formed on the substrate 104 of the CMOS die 101. The array die 102 and the CMOS die 101 are disposed face to face (the surface with circuitry disposed on is referred to as face, and the opposite surface is referred to as back), and bonded together.

In the FIG. 11 example, interconnection structures, such as a via 162, a metal wire 163, a bonding structure 164, and the like, can be formed to electrically couple the bottom portion of the semiconductor layer 185(D) to a bit line (BL).

Further in FIG. 11 example, the staircase region 116 includes a staircase that is formed to facilitate word line connections to the gates of transistors (e.g., memory cells, top select transistor(s), bottom select transistor(s) and the like). For example, the word line connection structure 150 includes a word line contact plug 151, a via structure 152, and metal wire 153 that are conductively coupled together. The word line connection structure 150 can electrically couple a WL to a gate terminal of a transistor in the memory cell string 180.

In the FIG. 11 example, the contact structures 170 are formed in the insulating region 117. In some embodiments, the contact structures 170 can be formed at the same time as the word line connection structures 150 by processing on the face side of the array die 102. Thus, in some examples, the contact structures 170 have similar structures as the word line connection structures 150. Specifically, a contact structure 170 can include a contact plug 171, a via structure 172, and metal wire 173 that are conductively coupled together.

In some examples, a mask that includes patterns for the contact plugs 171 and the word line contact plugs 151 can be used. The mask is used to form contact holes for the contact plugs 171 and the word line contact plugs 151. Etch process can be used to form the contact holes. In an example, etching of the contact holes for the word line contact plugs 151 can stop on the gate layers 195 and the etching of the contact holes for the contact plugs 171 can stop in the oxide layer 112. Further, the contact holes can be filled with suitable liner layer (e.g., titanium/titanium nitride) and a metal layer (e.g., tungsten) to form the contact plugs, such as the contact plugs 171 and the word line contact plugs 151. Further back end of line (BEOL) processes are used to form various connection structures, such via structures, metal wires, bonding structures, and the like.

Further, in the FIG. 11 examples, bonding structures are respectively formed on the face sides of the array die 102 and the CMOS die 101. For example, bonding structures 174 and 164 are formed on face side of the array die 102, and bonding structures 131 and 134 are formed on the face side of the CMOS die 101.

In the FIG. 11 example, the first wafer 501 including the array die 102 and the second wafer 502 including the CMOS die 101 are disposed face-to-face (circuitry side is face, and the substrate side is back) and bonded together. Accordingly, the array die 102 and the CMOS die 101 are disposed face-to-face and bonded together. Corresponding bonding structures on the first wafer 501 and the second wafer 502 are aligned and bonded together, and form a bonding interface that conductively couple suitable components on the two wafers. For example, the bonding structure 164 and the bonding structure 131 are bonded together to couple the drain side of the memory cell string 180 with a bit line (BL). In another example, the bonding structure 174 and the bonding structure 134 are bonded together to couple a contact structure 170 on the array die 102 with an I/O circuit on the CMOS die 101.

Referring to FIG. 11, in an example, the first wafer is the first wafer 501, the second wafer is the second wafer 502 (e.g., a peripheral wafer or a CMOS wafer). In an example, the contact structures 170, the word line connection structure 150, and the bonding structures 174 and 164 on the first wafer are formed after S216A where the flatness (e.g., bow) of the first wafer 501 satisfies the wafer flatness requirement. The bonding structures (e.g., 164, 174) of the first semiconductor device (e.g., the semiconductor memory device 100) on the first wafer (e.g., the first wafer 501) can be bonded with the respective bonding structures (e.g., 131, 134) of the peripheral wafer that includes peripheral circuitry to control the 3D NAND array.

In various examples, such as in 3D NAND memory device fabrication, a bow of an array wafer including 3D NAND array(s) and without bow compensation using the layer 199 is significantly larger than a bow of a peripheral wafer to be bonded with the array wafer. Accordingly, prior to the bonding step, the bow of the array wafer (e.g., the first wafer 501) is measured or predicted and then reduced by the layer 199. In an example, the bow of the peripheral wafer is not measured or predicted, and is not reduced as the bow of the peripheral wafer is relatively small. In an example, the bow of the peripheral wafer can be measured and/or predicted. The bow of the peripheral wafer can be reduced similarly as described with reference to S216A.

At S222A, the substrate of the first wafer can be removed from the back side of the first wafer. The removal of the first substrate exposes the semiconductor portion and the contact structures 170 on the back side of the first die or the first wafer.

In some examples, after a wafer-to-wafer bonding process, the first wafer 501 with array dies is bonded with the second wafer 502 with CMOS dies. Then, the first substrate is thinned from the back side of the first wafer 501. In an example, a chemical mechanical polishing (CMP) process or a grind process is used to remove a majority portion of the bulk portion 111 of the first wafer 501. Further, a suitable etch process can be used to remove remaining bulk portion 111, the silicon oxide layer 112 and the silicon nitride layer 113 from the back side of the first wafer 501.

In some examples, the step S222A can be adapted as follows. The bonded first wafer 501 and the second wafer 502 can be diced into a plurality of the bonded array die 102 and the CMOS die 101. Subsequently, the substrate of the array die 102 can be removed from the back side of array die 102 (e.g., the first die).

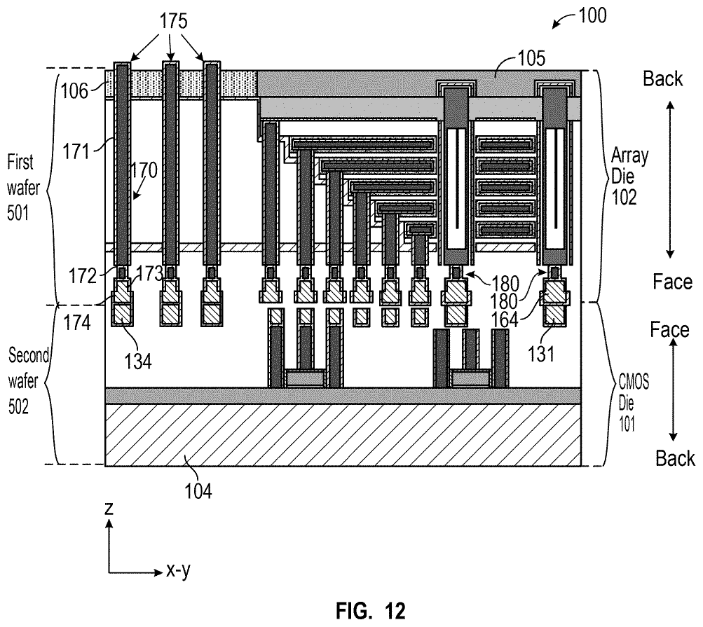

FIG. 12 shows a cross-sectional view of the semiconductor memory device 100 after the removal of the first substrate 103 from the array die 102 or the first wafer 501. In the FIG. 12 example, the bulk portion 111, the silicon oxide layer 112 and the silicon nitride layer 113 are removed from the back side of the array die 102 or the first wafer 501. The removal of the bulk portion 111, the silicon oxide layer 112 and the silicon nitride layer 113 can reveal the ends (as shown by 175) of the contact structures 170 that protrude from the insulating portions 106. The removal of the bulk portion 111, the silicon oxide layer 112 and the silicon nitride layer 113 can also reveal the semiconductor portion 105.

At S224A, pad structures and connection structures can be formed for the first semiconductor device at the back side of the first die on the first wafer. In some embodiments, the pad structures include first pad structures that are conductively connected with the contact structures 170. The connection structures are conductively connected with semiconductor portions 150.

In some embodiments, the pad structures and the connection structures are mainly formed of aluminum (Al). In some embodiments, interfacing layer(s) can be formed between the aluminum and the semiconductor portion 105. In some examples, metal silicide thin films can be used as the interfacing layer(s). In an example, a metal silicide thin film can be used to enable ohmic contacts between the aluminum and the semiconductor portion 105. In another example, a metal silicide thin film is used to form local interconnects to the semiconductor portion 105. In another example, a metal silicide thin film is used as diffusion barriers to prevent aluminum diffusion into the semiconductor portion 105.

In some examples, titanium is deposited overall on the back side of the first wafer that is face-to-face bonded with the second wafer, and is then heated in a nitrogen atmosphere. The titanium can react with exposed silicon surfaces (such as the semiconductor portion 105) to form titanium silicide. The portions (e.g., above the insulating portions, above the ends of the contact structures 170 and the like) of titanium which did not react to form silicide.

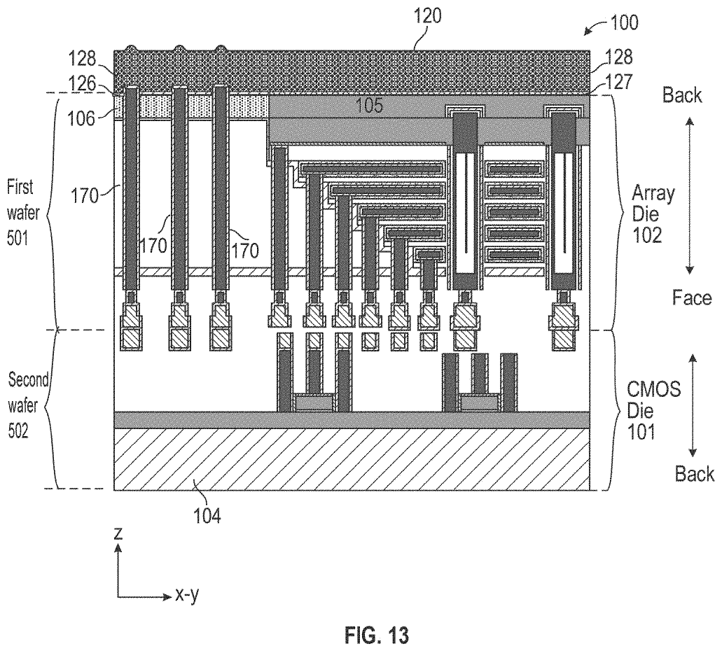

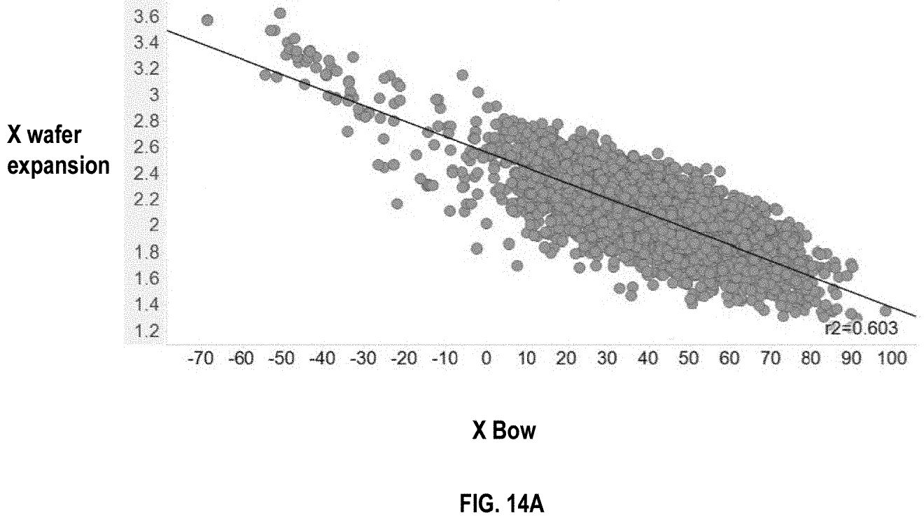

Then, metal film(s) can be formed on the surface of the back side of the first wafer. FIG. 13 shows a cross-sectional view of the semiconductor memory device 100 after the deposition of metal film(s). In the FIG. 13 example, a metal film 120 is deposited on the back side of the first wafer. The metal film 120 may have uneven surface due to the protrusion by the ends of the contact structures 170. In some embodiments, the metal film 120 includes a titanium layer 126 and an aluminum layer 128. In an embodiment, the titanium layer 126 on the semiconductor portion 105 can react with silicon surface to form titanium silicide 127. For example, the titanium layer 126 is deposited and heated in nitrogen atmosphere. Then the aluminum layer 128 is deposited.

The metal film 120 can be patterned to form pad structures and connection structures. FIG. 5 shows the cross-sectional view of the semiconductor memory device 100 after the metal film 120 is patterned into pad structures 122-123 and connection structure 121. In the FIG. 5 example, the pad structures 122-123 are respectively connected to the contact structures 170 and are disposed above the insulating portions 106; the connection structure 121 is connected to the semiconductor portion 105. In some embodiments, a photolithography process is used to define patterns for the pad structures 122-123 and the connection structure 121 into a photoresist layer according to a mask, then an etch process is used to transfer the patterns into the metal film 120 and to from the pad structures 122-123 and the connection structure 121.

The process 200A is described using a semiconductor memory device, such as the semiconductor memory device 100, as an example, and specific structures such as shown in FIG. 5 are formed. The process 200A including predicting the flatness of a wafer using the flatness prediction model can be suitably adapted to form other types of semiconductor devices or a same type of semiconductor devices with different and/or additional structures. One or more steps in the process 200A can be adapted or omitted. For example, S212A can be omitted, and thus the wafer flatness at T1 can be predicted using the flatness prediction model based on the at least one wafer expansion measured at T1. Any suitable order can be used to perform the process 200A. Additional step(s) can be added. The wafer fabrication process can continue further processes, such as, passivation, testing, dicing and the like.

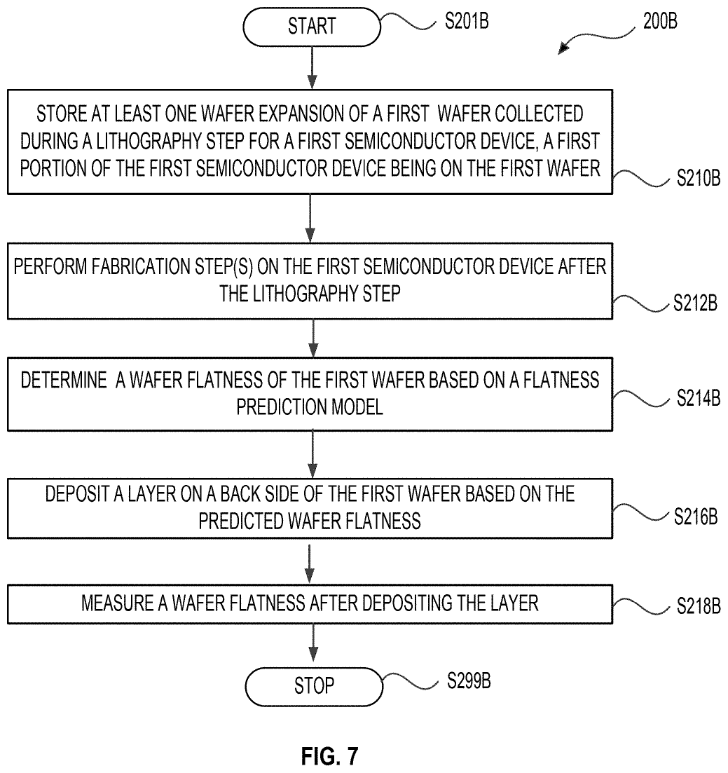

FIG. 7 shows a flow chart outlining a process 200B for determining a wafer flatness according to some embodiments of the disclosure. A portion of the process 200A shown in FIG. 6 is an example of the process 200B in FIG. 7. The process 200B starts at S201B, and proceeds to S210B.

At S210B, at least one wafer expansion of a first wafer is stored. The at least one wafer expansion of the first wafer can be collected or measured during a lithography process for a first semiconductor device (e.g., the semiconductor memory device 100). The at least one wafer expansion of the first wafer can be measured during the lithography process for the first semiconductor device, as described above with reference to S210A. A first portion of the first semiconductor device can be disposed on a face side of the first wafer, for example, over a working surface. An example of S210B is described in S210A with reference to FIGS. 6 and 8. In some embodiments, the first semiconductor device is the semiconductor memory device 100. The first wafer is the first wafer 501. In some embodiments, the first semiconductor device includes circuits that are different from NAND array(s).

The at least one wafer expansion of the first wafer can be measured during the lithography process, and a time when the lithography process is performed is referred to as the first time (e.g., T1). The at least one wafer expansion of the first wafer can include one or more wafer expansions along respective one or more directions within the X-Y plane (e.g., parallel to the working surface of the first wafer), such as an X wafer expansion along the X direction and/or a Y wafer expansion along the Y direction. In an example, the X direction is perpendicular to the Y direction.

At S212B, fabrication step(s) can be performed on the first semiconductor device after the lithography process. In an example, a second portion (e.g., the vertical memory cell strings 180 in FIG. 9) of the first semiconductor device can be formed on the first wafer after the lithography process. In an example, certain structures and/or materials are removed from the first semiconductor device.

As the fabrication steps include etching(s), multiple depositions of different materials, and the like, the first wafer can be in queue(s) between the etching(s) and the multiple depositions and wait to be processed. Thus, the first wafer can experience at least one wait time in the fabrication step(s), as described above. An example of S212B is described in S212A with reference to FIGS. 6 and 9.

At S214B, a wafer flatness of the first wafer after the fabrication step(s), can be determined (or predicted) based on the flatness prediction model.

The wafer flatness of the first wafer at the second time (e.g., T2) can be predicted. The second time can be after the fabrication step(s), as described in S214A.

As described above with reference to FIG. 6, the flatness prediction model is configured to determine the wafer flatness of the first wafer based on one or more of the at least one expansion that indicates the flatness at the first time (e.g., T1), such as at the lithography process, (ii) the at least one wait time between the first time (e.g., T1) and the second time (e.g., T2), (iii) one or more process parameters (e.g., a process temperature, a process time) of the respective fabrication step(s), and/or the like, such as described in Eqs. 1-5.

In an example, the wafer flatness is indicated by the bow of the first wafer, and the flatness prediction model is a bow prediction model that predicts the bow of the first wafer based on input(s) similar or identical to the input(s) to the flatness prediction model described above. The bow of the first wafer can be determined based on the bow prediction model.

In an example, the flatness prediction model is based on a machine learning algorithm and is updated based on measured wafer flatness and predicted wafer flatness of the third wafer, as described for the process 200A.

In an example, the third wafer is different from the first wafer, and no actual measurement is performed on the first wafer to determine the flatness of the first wafer at T2. The updated flatness prediction model can be employed to predict the flatness of the first wafer at T2.

In an example, the first wafer is the third wafer, and the above description can be adapted. The measurement of the at least one wafer expansion of the third wafer and the determination of the flatness of the third wafer using the flatness prediction model can be omitted. An example of S214B is described in S214A of FIG. 6.

At S216B, a layer can be deposited on a back side of the first wafer with a thickness that is based on the determined wafer flatness of the first wafer. In an example, the thickness is determined to adjust the wafer flatness for satisfying the wafer flatness requirement. In an example, the wafer flatness of the first wafer after depositing the layer satisfies the wafer flatness requirement. An example of S216B is described in S216A of FIG. 6.

At S218B, a wafer flatness of the first wafer after depositing the layer can be measured, for example, by an OCD measurement. An example of S218B is described in S218A of FIG. 6. If the measured wafer flatness (e.g., the measured bow) satisfies the wafer flatness requirement, the process 200B proceeds to S299B and terminates. Otherwise, the process 200B can either proceed to S299B or go back to S216B.

In addition to determining the flatness of the first wafer using the flatness prediction model and updating the flatness prediction model, the process 200B can include additional fabrication step(s) to form the first semiconductor device, such as bonding the first wafer to another wafer face to face as described in the process 200A of FIG. 6. One or more steps in the process 200B can be adapted or omitted. For example, S212B can be omitted, and thus the wafer flatness at T1 can be predicted using the flatness prediction model based on the at least one wafer expansion measured at T1. Any suitable order can be used to perform the process 200B. Additional step(s) can be added. The wafer fabrication process can continue further processes, such as, passivation, testing, dicing and the like.

In an example, flatness of a plurality of wafers is needed before a fabrication step having a wafer flatness requirement is performed, and a layer can be deposited on the wafer to adjust the flatness of the plurality of wafers. According to aspects of the disclosure, the processes 200A and 200B can be performed on the plurality of wafers as follows. Virtual flatness measurements can be performed on each of the plurality of wafers where the flatness prediction model is used to determine the flatness of the respective wafer. However, actual flatness measurements are only performed on a subset of the plurality of wafers, for example, to update the flatness prediction model. The subset of the plurality of wafers is a small set, such as 10%, of the plurality of wafers. Both the virtual flatness measurements and the actual flatness measurements can be performed prior to the layer deposition. In an example, results from the virtual flatness measurement and the actual flatness measurement for each wafer indicate the flatness of the wafer at T2 while the result of the virtual flatness measurement is based on expansion data measured at T1.

As described above, which fabrication step is selected as the first fabrication step where the wafer expansion is measured can be determined based on a device fabrication process and requirements. In an example, the wafer flatness (or the wafer bow) is to be determined for a fabrication step that is after forming contact structures (e.g., the contact structures 170 in FIG. 5) in a semiconductor device (e.g., the semiconductor device 100). Thus, the first fabrication step can be used to form the contact structures 170. Thus, the wafer expansion of a first wafer (e.g., the first wafer 501) in the semiconductor device (e.g., the semiconductor device 100) is measured using a lithography process that, for example, patterns contact holes for the contact plugs 171 and the word line contact plugs 151 in the contact structures 170 and the word line connection structures 150, respectively.

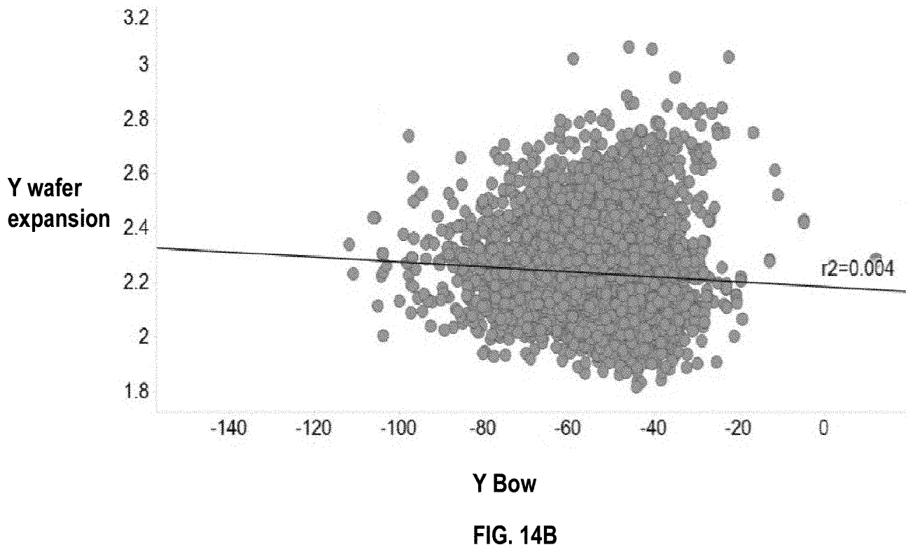

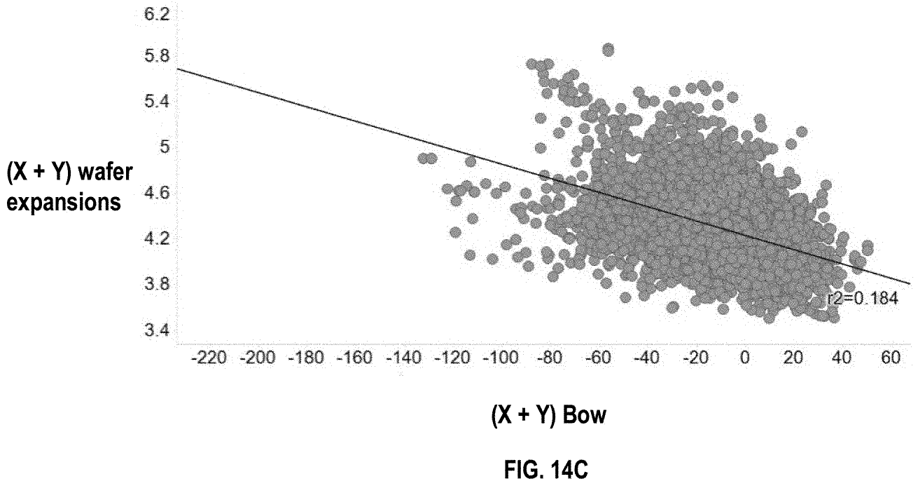

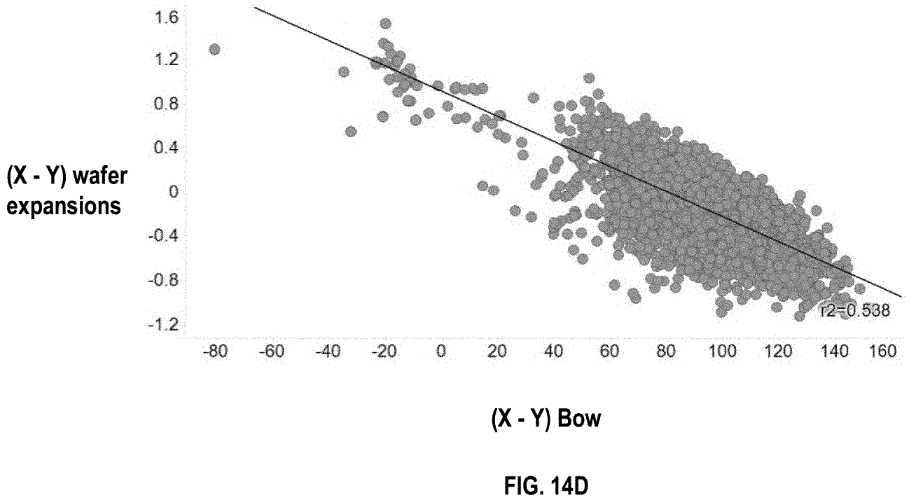

FIGS. 14A-14D show relationships between wafer expansions of wafers measured at a first time corresponding to a first fabrication step (or a first fabrication stage) and respective wafer flatness of the wafers measured at a second time corresponding to a second fabrication step (or a second fabrication stage) according to an embodiment of the disclosure. The first fabrication step can be performed prior to the second fabrication step.

In FIG. 14A, the vertical axis corresponds to an X wafer expansion along the X direction measured at the first time, and the horizontal axis corresponds to a first bow (or an X bow) of the wafer measured at the second time. The first bow of the wafer measured at the second time is prior to the deposition of a layer (e.g., the layer 199 in FIG. 10) to reduce the bow. Each data point represents the X wafer expansion and the first bow measurements for a wafer. Raw data (e.g., the data points) and a linear fit illustrate a linear relationship between the X wafer expansion and the measured first bow of the wafer. The linear relationship indicates that an X wafer expansion and a bow of the wafer corresponding to different fabrication steps (and different times) can have a linear relationship. Accordingly, the X wafer expansion corresponding to one fabrication step can be used to predict the bow of the wafer corresponding to another fabrication step.

In FIG. 14B, the vertical axis corresponds to a Y wafer expansion along the Y direction measured at the first time, and the horizontal axis corresponds to a second bow (or a Y bow) of the wafer measured at the second time. Each data point represents the Y wafer expansion and the second bow measurements for a wafer. Raw data (e.g., the data points) and a linear fit indicate a linear relationship between the Y wafer expansion measured at the first fabrication step, and the second bow of the wafer measured at the second fabrication step. Similarly as described with reference to FIG. 14A, the linear relationship indicates that a Y wafer expansion and a bow of the wafer corresponding to different fabrication steps can have a linear relationship. Accordingly, the Y wafer expansion corresponding to one fabrication step can be used to predict the bow of the wafer corresponding to another fabrication step.

In FIG. 14C, the vertical axis corresponds to a sum of the X wafer expansion and the Y wafer expansion corresponding to the first fabrication step, and the horizontal axis corresponds to a sum of the first bow and the second bow (or (X+Y) bow) of the wafer measured corresponding to the second fabrication step. Raw data (e.g., the data points) and a linear fits indicate a linear relationship between the sum of the X wafer expansion and the Y wafer expansion measured at the first fabrication step and the sum of the first bow and the second bow of the wafer measured corresponding to the second fabrication step.

In FIG. 14D, the vertical axis corresponds to a difference of the X wafer expansion and the Y wafer expansion corresponding to the first fabrication step, and the horizontal axis corresponds to a difference of the first bow and the second bow of the wafer (or (X-Y) bow) measured corresponding to the second fabrication step. Raw data (e.g., the data points) and a linear fit indicate a linear relationship between the difference of the X wafer expansion and the Y wafer expansion measured at the first fabrication step and the difference of the first bow and the second bow of the wafer measured corresponding to the second fabrication step.

In summary, FIGS. 14A-14D indicate an exemplary linear relationship between a wafer expansion corresponding to a first fabrication stage and a bow corresponding to a second fabrication stage. The bow corresponding to the second fabrication stage can be predicted based on the wafer expansion corresponding to the first fabrication stage.

On the other hand, although FIGS. 14A-14D indicate a linear relationship between the wafer expansion corresponding to the first fabrication stage and the bow corresponding to the second fabrication stage, the variations of the raw data from the respective linear fits are relatively large indicating that other variable(s) can affect the relationship between the wafer expansion corresponding to the first fabrication stage and the bow corresponding to the second fabrication stage. Such variables can include queue time(s), processing parameters, and/or the like.

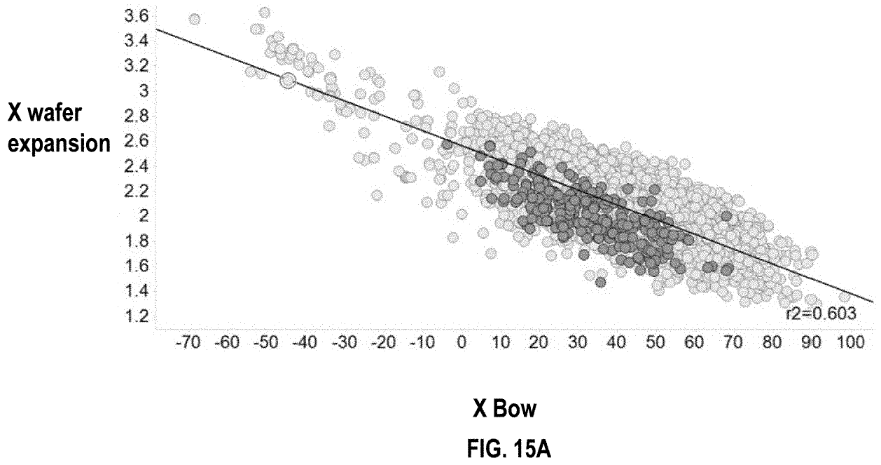

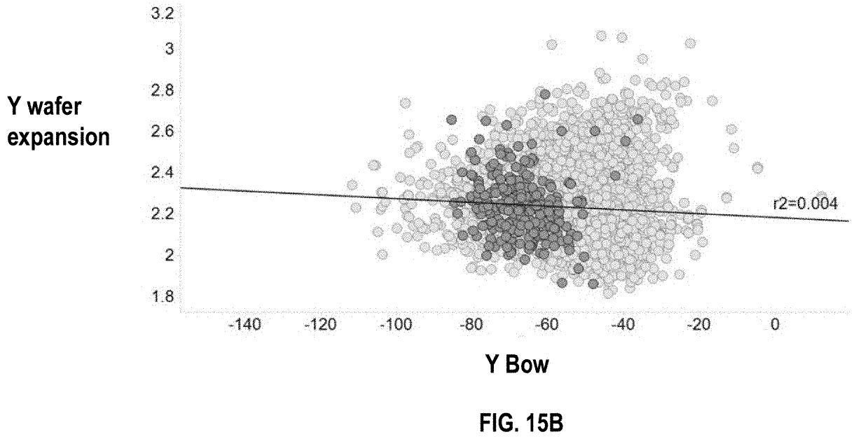

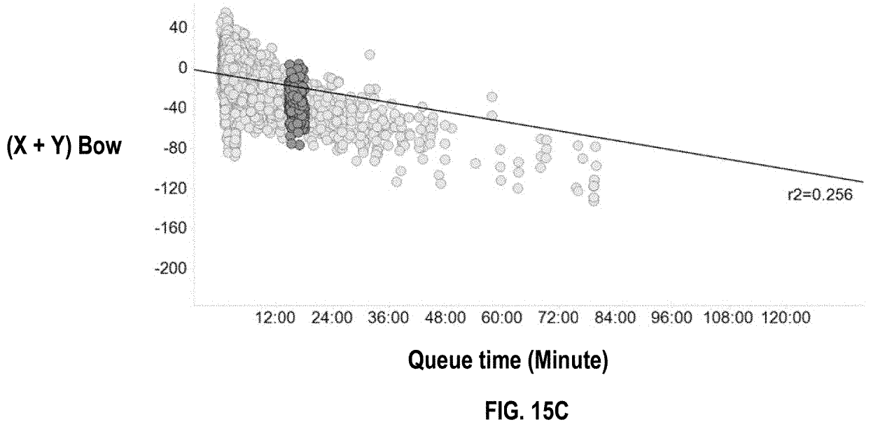

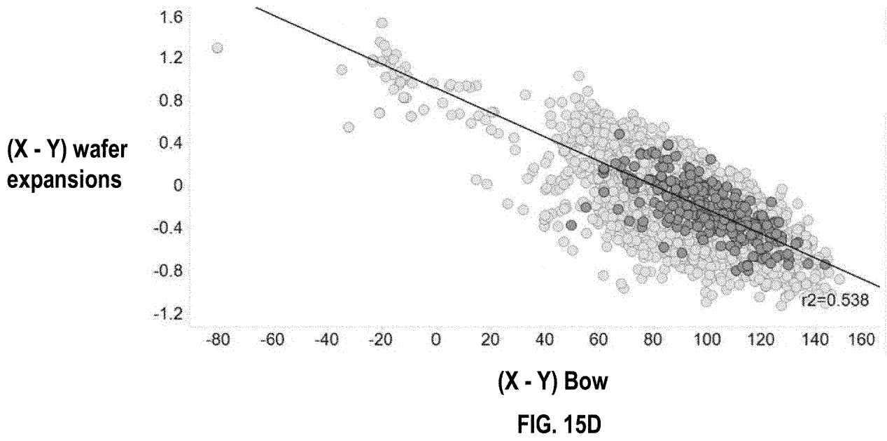

FIGS. 15A-15D show that the relationship between the wafer expansion corresponding to the first fabrication stage and the bow corresponding to the second fabrication stage can depend on a queue time according to an embodiment of the disclosure.

FIG. 15A corresponds to FIG. 14A where the horizontal axis and the vertical axis in FIG. 15A are identical to the horizontal axis and the vertical axis in FIG. 14A. The raw data and the linear fit in FIG. 14A are plotted in FIG. 15A using light circles.

The difference between FIGS. 15A and 14A is described below. In general, a queue time for one wafer can be different from a queue time for another wafer. In an example, a variation of the queue time among different wafers is large. An example of a queue time is a queue time (referred to as a CMP queue time) between a CMP to the second fabrication step when the bow is measured. In FIG. 14A, a range (e.g., a full range) of the CMP queue time can be relatively large (e.g., from 3 to 12 hours having a full range of 9 hours). However, in FIG. 15A, the data points (i.e., a subset of the raw data) shown in dark circles represent a subgroup of wafers having the CMP queue time constrained to be within a subrange of the CMP queue time, such as from 4 to 5 hours having the subrange of 1 hour.

Comparing FIGS. 14A and 15A, the flatness (e.g., the bow) of the wafer and the wafer expansion data in FIG. 15A have a better correlation (e.g., a larger correlation factor) than that in FIG. 14A by reducing the variation of a queue time (e.g., the CMP queue time). A comparison of the raw data in light circles and the subset of the raw data in dark circles in FIG. 15A shows that the flatness of a wafer (e.g., a bow of the wafer) at a later fabrication stage (e.g., the second fabrication stage) can depend on a queue time in addition to expansion data (e.g., an X expansion, a Y expansion, and/or the like). Accordingly, the flatness prediction model (e.g., the bow prediction model) can be made more accurate by incorporating one or more queue times, such as the CMP queue time.

FIG. 15B corresponds to FIG. 14B where the horizontal axis and the vertical axis in FIG. 15B are identical to the horizontal axis and the vertical axis in FIG. 14B. The raw data and the linear fits in FIG. 14B are shown in FIG. 15B using light circles. The difference between FIGS. 15B and 14B is similar to the difference between FIGS. 15A and 14A, as described above, and thus a detailed description is omitted for purposes of brevity.

FIG. 15D corresponds to FIG. 14D where the horizontal axis and the vertical axis in FIG. 15D are identical to the horizontal axis and the vertical axis in FIG. 14D. The raw data and the linear fits in FIG. 14D are shown in FIG. 15D using light circles. The difference between FIGS. 15D and 14D is similar to the difference between FIGS. 15A and 14A, as described above, and thus a detailed description is omitted for purposes of brevity.

Thus, comparison of FIGS. 14A and 15A, FIGS. 14B and 15B, and FIGS. 14D and 15D show that the wafer flatness or the wafer bow is dependent on the queue time, thus the flatness prediction model (e.g., the bow prediction model) can be more accurate by incorporating queue time(s), such as the CMP queue time.

FIG. 15C shows a relationship between a wafer flatness (e.g., a bow) versus a queue time (e.g., the CMP queue time) according to an embodiment of the disclosure. As shown here, the wafer flatness or the wafer bow, such as the sum of the first bow and the second bow (or (X+Y) bow) of the wafer, is dependent on the queue time, thus the flatness prediction model (e.g., the bow prediction model) can be more accurate by incorporating queue time(s), such as the CMP queue time.

FIGS. 14A-14D indicate exemplary linear relationships between the wafer expansion corresponding to the first fabrication stage and the bow corresponding to the second fabrication stage. In general, the wafer flatness (e.g., the bow) corresponding to the second fabrication stage can be dependent on one or more variables, such as the wafer expansion corresponding to the first fabrication stage and other variable(s) such as queue time(s), processing parameters, and/or the like. The wafer flatness (e.g., the bow) corresponding to the second fabrication stage can have a linear or a non-linear relationship with each of the one or more variables. The flatness prediction model (e.g., the bow prediction model) can predict the flatness (e.g., bow) corresponding to the second fabrication stage based on the linear or the non-linear relationship between the flatness and each of the one or more variables. In an example, such as described with reference to FIGS. 15A-15D, parameters characterizing the relationship (e.g., the linear relationship) between the flatness (e.g., bow) corresponding to the second fabrication stage and the wafer expansion corresponding to the first fabrication stage can be more accurate by taking into account other variable(s), such as the queue time.

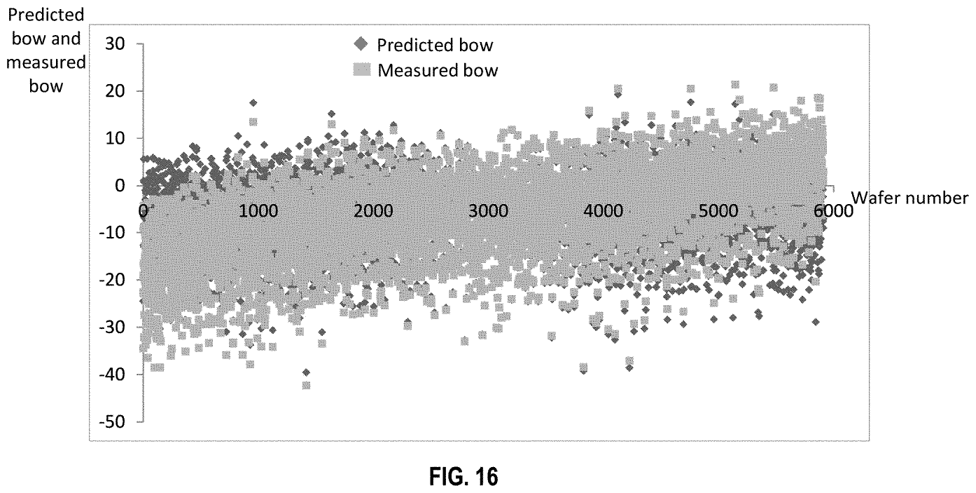

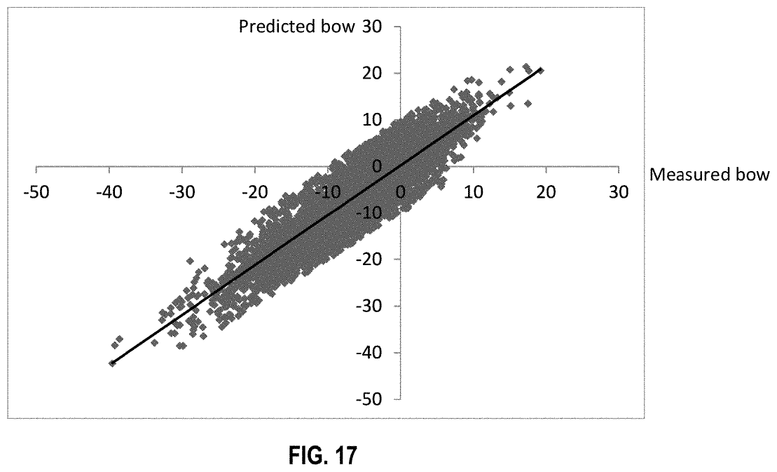

FIG. 16 shows a comparison of actual measured bow and predicted bow according to an embodiment of the disclosure. The horizontal axis represents wafers whose bow are actually measured and predicted. The vertical axis represents the actual measured bow (square shape) and the predicted bow (diamond shape). A correlation of the actual measured bow and the predicted bow are shown in FIG. 17 where the horizontal axis represents the actually measured bow and the vertical axis represents the predicted bow. FIG. 17 shows a linear trend with a correlation factor R² being 0.96, indicating that the flatness prediction model (e.g., the bow prediction model) is highly accurate.

The flatness prediction model can be updated based on the measured wafer flatness and the predicted wafer flatness, such as shown in FIGS. 16-17. As described above, the flatness prediction model can indicate the relationship between the flatness variable Fl and the one or more input variables, such as the X expansion variable Eₓ, the Y expansion variable E_{y}, queue time variables Qₜᵢₘₑ₁ to Qₜᵢₘₑᵢ that are associated with the fabrication step(s) between T1 and T2, process parameters (e.g., a process temperature, a process time, a process type) of the respective fabrication step(s), and/or the like. In an example, the flatness prediction model can be made more accurate when more input variables are taken into consideration in the flatness prediction mode, as shown in FIGS. 15A-15D where a queue time is included in addition to the expansion variables. Using similar approaches as described in FIGS. 15A-15D where the queue time is considered, the flatness prediction model can further include other input variables. The flatness prediction model can be made more accurate by including another input variable that are determined to have a relatively large influence.

In some examples, machine learning algorithms are used and are optimized by including more input variables in the flatness prediction model in addition to the X expansion variable Ex, the Y expansion variable Ey, and the queue time.

In some examples, a mathematical relationship between the flatness variable Fl and the one or more input variables such as shown in Eqs. 1-5 is obtained, and subsequently, the mathematical relationship can be made more accurate by comparing the measured wafer flatness and the predicted wafer flatness. In an example, mathematical relationships between the flatness variable Fl and expansion variables (e.g., the X expansion variable Ex and the Y expansion variable Ey) are obtained when different additional input variables (e.g., queue time variables, process parameters (e.g., a process temperature, a process time, a process type) of the respective fabrication step(s)) are considered.

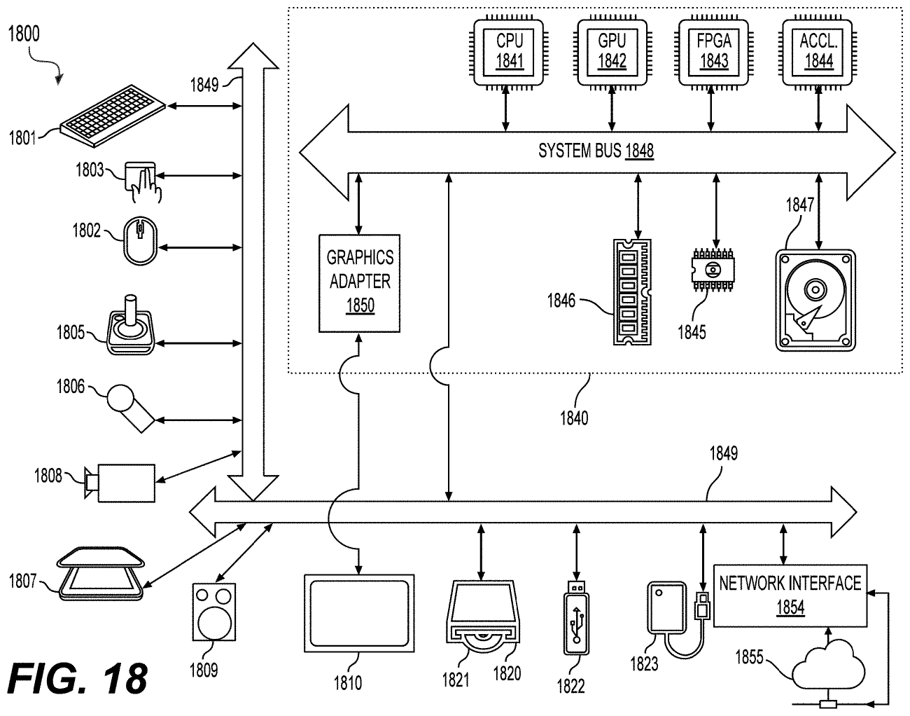

The methods described above, can be implemented as computer software using computer-readable instructions and physically stored in one or more computer-readable media such as a non-transitory computer-readable storage medium. In an example, the computer software can be embedded in a controller or other circuitry for semiconductor manufacturing equipment. In an example, the one or more computer-readable media can be read by the controller, a computing apparatus, or a computer system for semiconductor manufacturing equipment. For example, FIG. 18 shows a computer system (1800) suitable for implementing certain embodiments of the disclosure. The computer system (1800) can include the computing apparatus, and the computer apparatus can include processing circuitry that is configured to determine a wafer flatness using one or more of the methods described in the present disclosure.

The computer software can be coded using any suitable machine code or computer language, that may be subject to assembly, compilation, linking, or like mechanisms to create code comprising instructions that can be executed directly, or through interpretation, micro-code execution, and the like, by one or more computer central processing units (CPUs), Graphics Processing Units (GPUs), and the like.

The instructions can be executed on various types of computers or components thereof, including, for example, personal computers, tablet computers, servers, smartphones, gaming devices, internet of things devices, and the like. In an example, the instructions can be executed in a computing apparatus used in semiconductor manufacturing process.

The components shown in FIG. 18 for computer system (1800) are exemplary in nature and are not intended to suggest any limitation as to the scope of use or functionality of the computer software implementing embodiments of the present disclosure. Neither should the configuration of components be interpreted as having any dependency or requirement relating to any one or combination of components illustrated in the exemplary embodiment of a computer system (1800).

Computer system (1800) may include certain human interface input devices. Such a human interface input device may be responsive to input by one or more human users through, for example, tactile input (such as: keystrokes, swipes, data glove movements), audio input (such as: voice, clapping), visual input (such as: gestures), olfactory input (not depicted). The human interface devices can also be used to capture certain media not necessarily directly related to conscious input by a human, such as audio (such as: speech, music, ambient sound), images (such as: scanned images, photographic images obtain from a still image camera), video (such as two-dimensional video, three-dimensional video including stereoscopic video).

Input human interface devices may include one or more of (only one of each depicted): keyboard (1801), mouse (1802), trackpad (1803), touch screen (1810), data-glove (not shown), joystick (1805), microphone (1806), scanner (1807), camera (1808).

Computer system (1800) may also include certain human interface output devices. Such human interface output devices may be stimulating the senses of one or more human users through, for example, tactile output, sound, light, and smell/taste. Such human interface output devices may include tactile output devices (for example tactile feedback by the touch-screen (1810), data-glove (not shown), or joystick (1805), but there can also be tactile feedback devices that do not serve as input devices), audio output devices (such as: speakers (1809), headphones (not depicted)), visual output devices (such as screens (1810) to include CRT screens, LCD screens, plasma screens, OLED screens, each with or without touch-screen input capability, each with or without tactile feedback capability—some of which may be capable to output two dimensional visual output or more than three dimensional output through means such as stereographic output; virtual-reality glasses (not depicted), holographic displays and smoke tanks (not depicted)), and printers (not depicted).

Computer system (1800) can also include human accessible storage devices and their associated media such as optical media including CD/DVD ROM/RW (1820) with CD/DVD or the like media (1821), thumb-drive (1822), removable hard drive or solid state drive (1823), legacy magnetic media such as tape and floppy disc (not depicted), specialized ROM/ASIC/PLD based devices such as security dongles (not depicted), and the like. In an example, the computer system (1800) can include a solid state device (SSD) drive. The SSD drive can be implemented using a 3D NAND semiconductor device.

Those skilled in the art should also understand that term “computer readable media” as used in connection with the presently disclosed subject matter does not encompass transmission media, carrier waves, or other transitory signals.

Computer system (1800) can also include an interface (1854) to one or more communication networks (1855). Networks can for example be wireless, wireline, optical. Networks can further be local, wide-area, metropolitan, vehicular and industrial, real-time, delay-tolerant, and so on. Examples of networks include local area networks such as Ethernet, wireless LANs, cellular networks to include GSM, 3G, 4G, 5G, LTE and the like, TV wireline or wireless wide area digital networks to include cable TV, satellite TV, and terrestrial broadcast TV, vehicular and industrial to include CANBus, and so forth. Certain networks commonly require external network interface adapters that attached to certain general purpose data ports or peripheral buses (1849) (such as, for example USB ports of the computer system (1800)); others are commonly integrated into the core of the computer system (1800) by attachment to a system bus as described below (for example Ethernet interface into a PC computer system or cellular network interface into a smartphone computer system). Using any of these networks, computer system (1800) can communicate with other entities. Such communication can be uni-directional, receive only (for example, broadcast TV), uni-directional send-only (for example CANbus to certain CANbus devices), or bi-directional, for example to other computer systems using local or wide area digital networks. Certain protocols and protocol stacks can be used on each of those networks and network interfaces as described above.

Aforementioned human interface devices, human-accessible storage devices, and network interfaces can be attached to a core (1840) of the computer system (1800).

The core (1840) can include one or more Central Processing Units (CPU) (1841), Graphics Processing Units (GPU) (1842), specialized programmable processing units in the form of Field Programmable Gate Areas (FPGA) (1843), hardware accelerators for certain tasks (1844), graphics adapters (1850), and so forth. These devices, along with Read-only memory (ROM) (1845), Random-access memory (1846), internal mass storage such as internal non-user accessible hard drives, SSDs, and the like (1847), may be connected through a system bus (1848). In some computer systems, the system bus (1848) can be accessible in the form of one or more physical plugs to enable extensions by additional CPUs, GPU, and the like. The peripheral devices can be attached either directly to the core's system bus (1848), or through a peripheral bus (1849). In an example, the screen (1810) can be connected to the graphics adapter (1850). Architectures for a peripheral bus include PCI, USB, and the like.

CPUs (1841), GPUs (1842), FPGAs (1843), and accelerators (1844) can execute certain instructions that, in combination, can make up the aforementioned computer code. That computer code including the methods disclosed in the present disclosure can be stored in ROM (1845) or RAM (1846). Transitional data can be also be stored in RAM (1846), whereas permanent data can be stored for example, in the internal mass storage (1847). Fast storage and retrieve to any of the memory devices can be enabled through the use of cache memory, that can be closely associated with one or more CPU (1841), GPU (1842), mass storage (1847), ROM (1845), RAM (1846), and the like.

The computer readable media can have computer code thereon for performing various computer-implemented operations. The media and computer code can be those specially designed and constructed for the purposes of the present disclosure, or they can be of the kind well known and available to those having skill in the computer software arts.

As an example and not by way of limitation, the computer system having architecture (1800), and specifically the core (1840) can provide functionality as a result of processor(s) (including CPUs, GPUs, FPGA, accelerators, and the like) executing software embodied in one or more tangible, computer-readable media. Such computer-readable media can be media associated with user-accessible mass storage as introduced above, as well as certain storage of the core (1840) that are of non-transitory nature, such as core-internal mass storage (1847) or ROM (1845). The software implementing various embodiments of the present disclosure can be stored in such devices and executed by core (1840). A computer-readable medium can include one or more memory devices or chips, according to particular needs. The software can cause the core (1840) and specifically the processors therein (including CPU, GPU, FPGA, and the like) to execute particular processes or particular parts of particular processes described herein, including defining data structures stored in RAM (1846) and modifying such data structures according to the processes defined by the software. In addition or as an alternative, the computer system can provide functionality as a result of logic hardwired or otherwise embodied in a circuit (for example: accelerator (1844)), which can operate in place of or together with software to execute particular processes or particular parts of particular processes described herein. Reference to software can encompass logic, and vice versa, where appropriate. Reference to a computer-readable media can encompass a circuit (such as an integrated circuit (IC)) storing software for execution, a circuit embodying logic for execution, or both, where appropriate. The present disclosure encompasses any suitable combination of hardware and software.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for determining wafer flatness, comprising:
storing a first wafer expansion of a first wafer that is collected along a first direction parallel to a working surface of the first wafer during a lithography process for patterning structures on the working surface of the first wafer; and
before a fabrication step with a wafer flatness requirement, determining a wafer flatness of the first wafer based on the first wafer expansion collected during the lithography process using a flatness prediction model that is configured to predict the wafer flatness.

2. The method according to claim 1, further comprising:
depositing a layer on a back side of the first wafer with a thickness that is based on the determined wafer flatness of the first wafer.

3. The method according to claim 1, wherein:
the method further includes measuring a second wafer expansion along a second direction parallel to the working surface of the first wafer, the first direction being perpendicular to the second direction; and
the determining includes determining the wafer flatness of the first wafer based on the first wafer expansion and the second wafer expansion using the flatness prediction model.

4. The method according to claim 1, wherein
the method further includes, after the lithography process and prior to the determining step, modifying the first wafer by forming the structures on the working surface of the first wafer using a plurality of fabrication steps, and
the determining includes determining the wafer flatness of the first wafer based on the first wafer expansion and a wait time between two of the plurality of fabrication steps using the flatness prediction model.

5. The method according to claim 1, wherein
the wafer flatness is indicated by a bow of the first wafer,
the flatness prediction model is a bow prediction model that predicts the bow of the first wafer, and
the determining includes determining the bow of the first wafer based on the first wafer expansion using the bow prediction model.

6. The method according to claim 1, wherein:
the flatness prediction model is based on a machine learning algorithm; and
the method further includes:
measuring a wafer expansion of a second wafer along a direction that is parallel to the working surface of the second wafer during a lithography process for patterning structures on the working surface of the second wafer;
before the fabrication step with the wafer flatness requirement is performed on the second wafer,
determining a wafer flatness of the second wafer based on the wafer expansion of the second wafer using the flatness prediction model; and
measuring an actual wafer flatness of the second wafer; and
updating the flatness prediction model based on the measured wafer flatness of the second wafer and the determined wafer flatness of the second wafer.

7. The method according to claim 1, wherein the lithography process is a lithography process that is performed closest in time to the fabrication step with the wafer flatness requirement.

8. The method according to claim 4, wherein the determining comprises:
determining the wafer flatness of the first wafer based on a processing temperature or a processing time of one of the plurality of fabrication steps using the flatness prediction model, the flatness prediction model being dependent on the first wafer expansion, the wait time, and one of the processing temperature and the processing time of one of the plurality of fabrication steps.

9. The method according to claim 1, wherein the fabrication step with the wafer flatness requirement is performed after formation of contact structures and word line contacts.

10. The method according to claim 1, wherein the structures include contact structures and word line contacts, and the lithography process patterns the contact structures and the word line contacts.

11. A method for fabricating a semiconductor device, comprising:
obtaining a first wafer expansion of a first wafer that is collected along a first direction parallel to a working surface of the first wafer during a lithography process for patterning structures of the semiconductor device on the working surface of the first wafer;
before a bonding step with a wafer flatness requirement, determining a wafer flatness of the first wafer based on the first wafer expansion using a flatness prediction model that is configured to predict the wafer flatness,
depositing a layer on a back side of the first wafer with a thickness that is determined based on the determined wafer flatness of the first wafer; and
bonding, face to face, the first wafer with a second wafer.

12. The method according to claim 11, wherein the wafer flatness of the first wafer after depositing the layer satisfies the wafer flatness requirement.

13. The method according to claim 11, wherein:
the method further includes measuring a second wafer expansion along a second direction parallel to the working surface of the first wafer, the first direction being perpendicular to the second direction, and
the determining includes determining the wafer flatness of the first wafer based on the first wafer expansion and the second wafer expansion using the flatness prediction model.

14. The method according to claim 11, wherein
the method further includes, after the lithography process and prior to the determining step, modifying the first wafer by forming the structures on the working surface of the first wafer using a plurality of fabrication steps, and
the determining includes determining the wafer flatness of the first wafer based on the first wafer expansion and a wait time between two of the plurality of fabrication steps using the flatness prediction model configured to predict the wafer flatness.

15. The method according to claim 11, wherein
the wafer flatness is indicated by a bow of the first wafer,
the flatness prediction model is a bow prediction model, and
the determining includes determining the bow of the first wafer based on the first wafer expansion using the bow prediction model that predicts the bow of the first wafer.

16. The method according to claim 11, wherein:
the flatness prediction model is based on a machine learning algorithm; and
the method further includes:
measuring a wafer expansion of a third wafer along a direction that is parallel to the working surface of the third wafer during a lithography process for patterning structures on the working surface of the third wafer;
before the bonding step with a wafer flatness requirement is performed on the third wafer,
determining a wafer flatness of the third wafer using the flatness prediction model; and
measuring an actual wafer flatness of the third wafer; and
updating the flatness prediction model based on the measured wafer flatness of the third wafer and the determined wafer flatness of the third wafer.

17. The method according to claim 16, further comprising:
depositing a layer on a back side of the third wafer with a thickness that is based on the determined wafer flatness of the third wafer.

18. The method according to claim 14, wherein the determining comprises:
determining the wafer flatness of the first wafer based on a processing temperature or a processing time of one of the plurality of fabrication steps using the flatness prediction model, the flatness prediction model being dependent on the first wafer expansion, the wait time, and one of the processing temperature and the processing time of one of the plurality of fabrication steps.

19. The method according to claim 11, wherein the semiconductor device is a semiconductor memory device including a 3D NAND array, the first wafer includes a plurality of 3D NAND arrays, and the second wafer includes peripheral circuitry to control the 3D NAND array.

20. The method according to claim 11, wherein the bonding step with the wafer flatness requirement is performed after formation of contact structures and word line contacts.

21. The method according to claim 11, wherein the structures include contact structures and word line contacts, and the lithography process patterns the contact structures and the word line contacts.

22. The method according to claim 11, wherein
the structures of the semiconductor device include channel structures of a 3D NAND array, and
the determining further includes determining, based on the first wafer expansion, the wafer flatness of the first wafer using the flatness prediction model prior to fabricating word line contacts of the semiconductor device and after the formation of the channel structures of the 3D NAND array.

23. The method according to claim 11, wherein the lithography process is a lithography process that is performed closest in time to the fabrication step with the wafer flatness requirement.

24. A computing apparatus, comprising processing circuitry configured to:
store a wafer expansion of a wafer that is collected along a first direction parallel to a working surface of the wafer during a lithography process for patterning structures on the working surface of the wafer; and
before a fabrication step with a wafer flatness requirement, determine a wafer flatness of the wafer based on the wafer expansion collected during the lithography process using a flatness prediction model that is configured to predict the wafer flatness.

25. A non-transitory computer-readable storage medium storing a program executable by one or more processors to perform:
storing a wafer expansion of a wafer that is collected along a first direction parallel to a working surface of the wafer during a lithography process for forming structures on the working surface of the wafer; and
before a fabrication step with a wafer flatness requirement, determining a wafer flatness of the wafer based on the wafer expansion collected during the lithography process using a flatness prediction model that is configured to predict the wafer flatness.
